(19) United States
(12) Patent Application Publication
(10) Pub. No.: US 2025/0062240 A1
(43) Pub. Date: Feb. 20, 2025

(54) SEMICONDUCTOR PACKAGE WITH IMPROVED STRUCTURAL STABILITY

(71) Applicant: SAMSUNG ELECTRONICS CO., LTD., Suwon-si (KR)

(72) Inventors: MyungDo Cho, Suwon-si (KR); Youngchan Ko, Suwon-si (KR); Byung Ho Kim, Suwon-si (KR); Yongkoon Lee, Suwon-si (KR); Jeongho Lee, Suwon-si (KR)

(21) Appl. No.: 18/611,488

(22) Filed: Mar. 20, 2024

(30) Foreign Application Priority Data
Aug. 18, 2023 (KR) 10-2023-0108510

(51) Int. Cl. H01L 23/538; H01L 23/00; H01L 23/31; H01L 23/498; H01L 25/065

(52) U.S. Cl. CPC H01L 23/5386; H01L 23/3128; H01L 23/49811; H01L 24/20; H01L 25/0652; H01L 24/16; H01L 2224/16227; H01L 2224/21; H01L 2225/06541

(57) ABSTRACT

An example semiconductor package includes a first redistribution layer, a bridge chip attached to a top surface of the first redistribution layer, a mold layer on the first redistribution layer and enclosing the bridge chip, a second redistribution layer disposed on the mold layer, a conductive post extending through the mold layer vertically and connecting the first redistribution layer and the second redistribution layer, and a first semiconductor chip mounted on the second redistribution layer. The first redistribution layer includes a pad layer and an interconnection layer disposed on the pad layer. The pad layer includes a first insulating layer and pads in the first insulating layer. Top surfaces of the pads are exposed to an outside of a top surface of the first insulating layer, and bottom surfaces of the pads are exposed to an outside of a bottom surface of the first insulating layer.

### CROSS-REFERENCE TO RELATED APPLICATION

This application claims priority under 35 U.S.C. § 119 to Korean Patent Application No. 10-2023-0108510, filed on Aug. 18, 2023, in the Korean Intellectual Property Office, the entire disclosure of which is hereby incorporated by reference.

### BACKGROUND

In light of recent advancements in the electronics industry, the demand for high-performance, high-speed, and compact electronic components has been steadily increasing. As a result, there is a development of packaging technologies that allow for the mounting of multiple semiconductor chips within a single package.

To reduce the size and weight of the electronic component, it is necessary to develop technologies of reducing a size of each component and packaging technologies of integrating several components in a single package. In particular, for a semiconductor package used to process high frequency signals, it is necessary not only to reduce a size of a product but also to realize good electrical characteristics.

In general, a through-silicon via (TSV) process, a flip chip process, a wire bonding process, or the like is used to stack a plurality of memory chips on a package substrate. However, the TSV process suffers from high complexity and cost, and thus, it is necessary to develop a process capable of overcoming these difficulties in the TSV process.

A semiconductor package is configured to facilitate the use of an integrated circuit chip as a component in an electronic product. In general, the semiconductor package includes a printed circuit board (PCB) and a semiconductor chip, which is mounted on the PCB and is electrically connected to the PCB by bonding wires or bumps. With the recent development of the electronics industry, a semiconductor package technology is developing in various ways with the goal of miniaturization, weight reduction, and manufacturing cost reduction. Furthermore, as the utilization of this technology expands to different fields, including mass storage devices, several types of semiconductor packages are emerging.

### SUMMARY

The present disclosure relates to semiconductor packages, including a semiconductor package with improved structural stability and a semiconductor package with a small size and a high integration density, and methods of fabricating the same, including a method of reducing a failure rate in a process of fabricating a semiconductor package.

In some implementations, a semiconductor package includes a first redistribution layer, a bridge chip provided on and attached to a top surface of the first redistribution layer, a mold layer provided on the first redistribution layer to enclose the bridge chip, a second redistribution layer disposed on the mold layer, a conductive post provided to vertically penetrate the mold layer and to connect the first redistribution layer to the second redistribution layer, and a first semiconductor chip mounted on the second redistribution layer. The first redistribution layer may include a pad layer and an interconnection layer disposed on the pad layer. The pad layer may include a first insulating layer and pads provided in the first insulating layer. Top surfaces of the pads may be exposed to an outside of the first insulating layer near a top surface of the first insulating layer, and bottom surfaces of the pads may be exposed to an outside of the first insulating layer near a bottom surface of the first insulating layer. A surface flatness of a top surface of the pad layer may be greater than a surface flatness of a bottom surface of the pad layer.

In some implementations, a semiconductor package includes a first redistribution layer, a bridge chip on the first redistribution layer, a mold layer provided on the first redistribution layer to enclose the bridge chip, a second redistribution layer disposed on the mold layer, a conductive post provided to vertically penetrate the mold layer and to connect the first redistribution layer to the second redistribution layer, and a first semiconductor chip mounted on the second redistribution layer. The first redistribution layer may include a substrate protection layer and a pad layer, which includes outer pads vertically penetrating the substrate protection layer, a top surface of the substrate protection layer and top surfaces of the outer pads being substantially flat and being coplanar with each other, an insulating pattern covering the substrate protection layer and the outer pads, and interconnection patterns disposed on the insulating pattern. The interconnection pattern may include a head portion placed on a top surface of the insulating pattern and a tail portion extended from a bottom surface of the head portion to vertically penetrate the insulating pattern and connected to the outer pads. A total thickness variation (TTV) of the pad layer may range from 0 μm to 10 μm.

In some implementations, a semiconductor package includes a first redistribution layer, a second redistribution layer disposed on the first redistribution layer, a bridge chip mounted on a bottom surface of the second redistribution layer, a mold layer enclosing the bridge chip, between the first and second redistribution layers, a conductive post provided to vertically penetrate the mold layer and to connect the first redistribution layer to the second redistribution layer, a first semiconductor chip mounted on a top surface of the second redistribution layer, and a chip stack including second semiconductor chips, which are vertically stacked on the top surface of the second redistribution layer to be horizontally spaced apart from the first semiconductor chip. The first redistribution layer may include a pad layer including outer pads and a substrate protection layer, which horizontally encloses the outer pads, an insulating pattern covering the outer pads and the substrate protection layer, and an interconnection pattern disposed on the insulating pattern to penetrate the insulating pattern and coupled to the outer pads. Top surfaces of the outer pads may be exposed to an outside of the substrate protection layer near a top surface of the substrate protection layer, and a top surface of the pad layer may be substantially flat. Bottom surfaces of the outer pads may be exposed to an outside of the substrate protection layer near a bottom surface of the substrate protection layer, and a bottom surface of the pad layer may be uneven.

In some implementations, a method of fabricating a semiconductor package includes forming a sacrificial layer on a carrier substrate, performing an exposure process on the carrier substrate to form openings vertically penetrating the sacrificial layer, filling the openings with a conductive material to form pads, removing the sacrificial layer, forming a substrate protection layer on the carrier substrate to cover the pads, performing a first planarization process on the substrate protection layer and the pads to expose the pads from the substrate protection layer near a top surface of the substrate protection layer, forming an insulating layer on the substrate protection layer and the pads, patterning the insulating layer to form an insulating pattern, forming a conductive layer on the insulating pattern and patterning the conductive layer to form an interconnection pattern, forming conductive posts on the interconnection pattern, attaching a bridge chip to the insulating pattern, forming a mold layer on the insulating pattern to cover the conductive posts and the bridge chip, and performing a second planarization process on the mold layer to expose the conductive posts from the mold layer near a top surface of the mold layer.

### BRIEF DESCRIPTION OF THE DRAWINGS

FIG. 1 is a sectional view illustrating an example of a semiconductor package.

FIG. 2 is an example enlarged sectional view illustrating a portion ‘A’ of FIG. 1.

FIGS. 3 to 8 are sectional views, each of which illustrates an example of a semiconductor package.

FIGS. 9A, 10A, 11A, 12A, 13A, 14A, 15A, 16A, and 17 are sectional views illustrating an example of a method of fabricating a semiconductor package.

FIGS. 9B, 10B, 11B, 12B, 13B, 14B, 15B, and 16B are example enlarged sectional views illustrating portions ‘B’ of FIGS. 9A, 10A, 11A, 12A, 13A, 14A, 15A, and 16A.

### DETAILED DESCRIPTION

Example implementations of the present disclosure will now be described more fully with reference to the accompanying drawings, in which example implementations are shown.

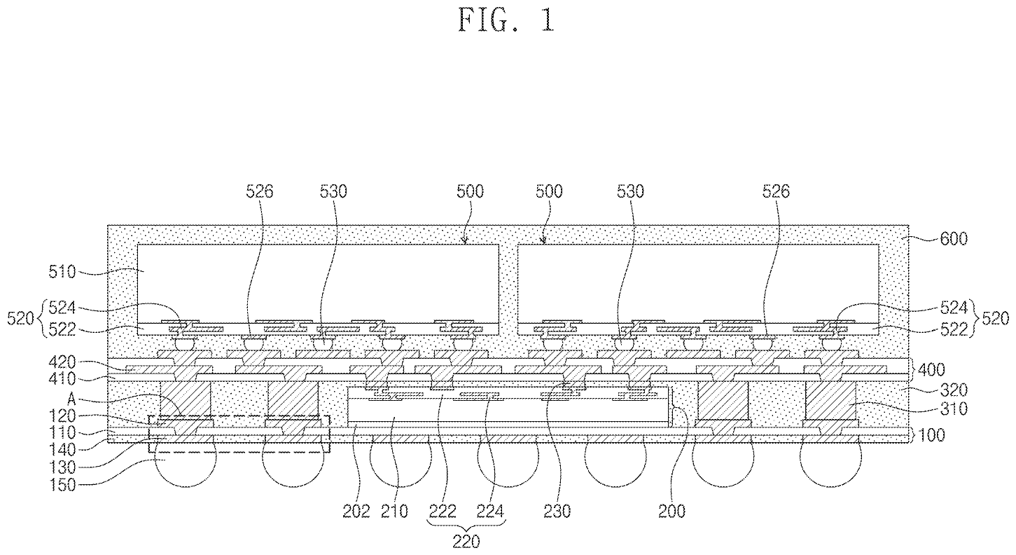

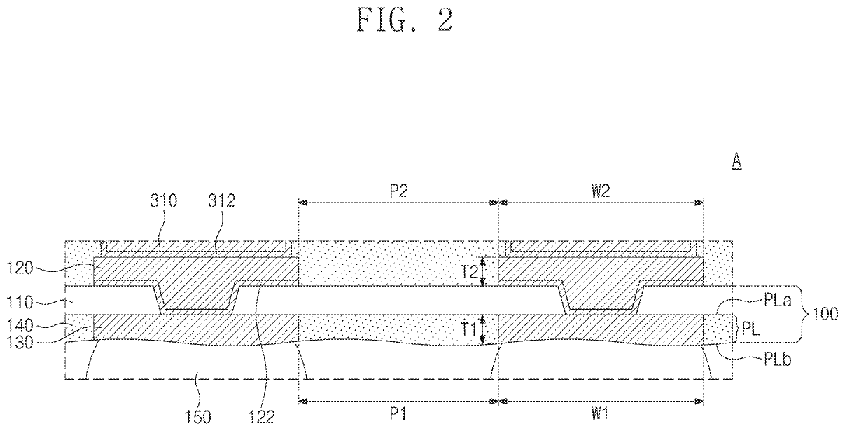

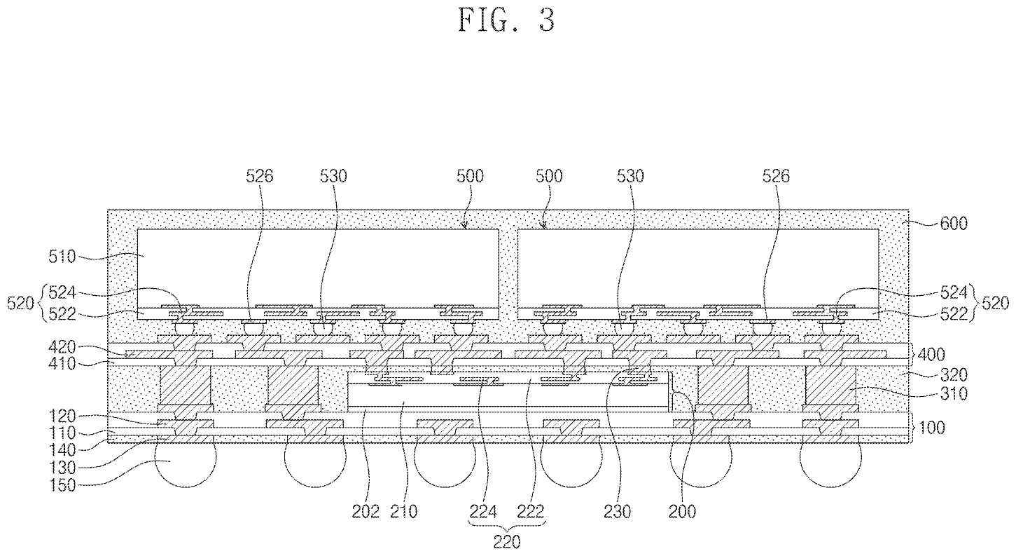

FIG. 1 is a sectional view illustrating an example of a semiconductor package. FIG. 2 is an example enlarged sectional view illustrating a portion ‘A’ of FIG. 1. FIG. 3 is a sectional view illustrating an example of a semiconductor package.

Referring to FIGS. 1 and 2, a first redistribution layer 100 is provided. For example, the first redistribution layer 100 may include one first substrate interconnection layer, which is composed of a first substrate insulating pattern 110 and a first substrate interconnection pattern 120 on the first substrate insulating pattern 110.

The first substrate insulating pattern 110 may be formed of or include at least one of insulating polymers or photoimageable polymers (e.g., photoimageable dielectric (PID) materials). For example, the photoimageable polymers may include at least one of photoimageable polyimide (PI), polybenzoxazole (PBO), phenol-based polymers, or benzocyclobutene-based polymers.

First substrate interconnection patterns 120 may be provided on the first substrate insulating pattern 110. The first substrate interconnection patterns 120 on the first substrate insulating pattern 110 may be horizontally extended. The first substrate interconnection patterns 120 may be provided on a top surface of the first substrate insulating pattern 110. The first substrate interconnection pattern 120 may include a protruding portion that is extended to a level higher than the top surface of the first substrate insulating pattern 110. At least one of the first substrate interconnection patterns 120 may be used as a redistribution pad that is coupled to a conductive post 310. Here, the first substrate interconnection patterns 120 serving as the redistribution pads may be placed on an edge region of the first redistribution layer 100. Although not shown, at least one of the first substrate interconnection patterns 120 may be horizontally extended, on the first substrate insulating pattern 110. As described above, the first substrate interconnection pattern 120 may be a pad portion or a wire portion of the first substrate interconnection layer. In other words, the first substrate interconnection patterns 120 may be an element for a horizontal redistribution in the first redistribution layer 100. The first substrate interconnection patterns 120 may include a conductive material. For example, the first substrate interconnection patterns 120 may be formed of or include at least one of metallic materials (e.g., copper (Cu)).

The first substrate interconnection patterns 120 may have a damascene structure. For example, each or at least some of the first substrate interconnection patterns 120 may include a via portion, which is protrudingly extended from a bottom surface thereof. The via portion may be an element, which is used for a vertical interconnection in the first substrate interconnection layer. For example, the via portion may be extended from the bottom surface of the first substrate interconnection pattern 120 to penetrate the first substrate insulating pattern 110 and may be coupled to top surfaces of outer pads 130, which will be described below. An upper portion of the first substrate interconnection pattern 120, which is placed on the first substrate insulating pattern 110, may be a head portion, which is used for a horizontal interconnection or as a pad, and the via portion of the first substrate interconnection patterns 120 may be a tail portion. A width of the tail portion may be smaller than a width of the head portion. The width of the tail portion may decrease as a distance from the head portion of the first substrate interconnection pattern 120 increases. That is, the tail portion may have a tapered shape. Each or at least some of the first substrate interconnection patterns 120 may have the shape of the letter ‘T’.

First seed/barrier layers 122 may be provided between the first substrate interconnection patterns 120 and the first substrate insulating pattern 110. As shown in FIG. 2, each of the first seed/barrier layers 122 may cover a bottom surface of a corresponding one the first substrate interconnection patterns 120. The first seed/barrier layers 122 may conformally cover the bottom surfaces of the first substrate interconnection patterns 120. The first seed/barrier layers 122 may be provided to expose side surfaces of the first substrate interconnection patterns 120. However, in some implementations, each of the first seed/barrier layers 122 may be provided to cover bottom and side surfaces of a corresponding one of the first substrate interconnection patterns 120. In this case, the first seed/barrier layers 122 may conformally cover the bottom and side surfaces of the first substrate interconnection patterns 120. A distance between the first substrate insulating pattern 110 and the first substrate interconnection patterns 120 (i.e., the thickness of the first seed/barrier layers 122) may range from 50 Å to 1000 Å. In the case where the first seed/barrier layers 122 are used as a seed layer, the first seed/barrier layers 122 may include a metallic material, such as gold (Au). In the case where the first seed/barrier layers 122 are used as a barrier layer, the first seed/barrier layers 122 may include a metallic material, such as titanium (Ti) and tantalum (Ta), or a metal nitride material, such as titanium nitride (TiN) and tantalum nitride (TaN). In some implementations, the first seed/barrier layers 122 may not be provided.

FIGS. 1 and 2 illustrate an example, in which the first redistribution layer 100 has one first substrate interconnection layer, but the present disclosure is not limited to this example. For example, the first redistribution layer 100 may include at least two first substrate interconnection layers, which are sequentially stacked, as shown in FIG. 3. The first substrate interconnection pattern 120 of one of the first substrate interconnection layers may be electrically connected to the first substrate interconnection pattern 120 of another first substrate interconnection layer adjacent thereto. The first substrate interconnection patterns 120 on the first substrate insulating pattern 110 may be covered with another first substrate insulating pattern 110 which is disposed thereon. The first substrate interconnection patterns 120, which are provided in the uppermost one of the first substrate interconnection layers, may be used as redistribution pads, to which the conductive posts 310 are coupled. The via portion of the first substrate interconnection pattern 120 may be an element, which is used to vertically connect the first substrate interconnection patterns 120 of adjacent ones of the first substrate interconnection layers. For example, the via portion may be extended from the bottom surface of the first substrate interconnection pattern 120 to penetrate the first substrate insulating pattern 110 and may be coupled to a top surface of the first substrate interconnection pattern 120 of another first substrate interconnection layer thereunder. Alternatively, the via portion may be an element, which is used to connect the first substrate interconnection patterns 120 in the lowermost one of the first substrate interconnection layers to the outer pads 130. For example, the via portion may be extended from the bottom surface of the first substrate interconnection pattern 120 to penetrate the lowermost one of the first substrate insulating patterns 110 and may be coupled to the top surfaces of the outer pads 130. For brevity's sake, the description that follows will refer to the implementation of FIGS. 1 and 2.

The first redistribution layer 100 may further include a pad layer PL, which is provided below the first substrate interconnection layer. The pad layer PL may be composed of a substrate protection layer 140 and the outer pads 130, which are provided in the substrate protection layer 140.

The outer pads 130 may be provided on a bottom surface of the first substrate interconnection layer. The outer pads 130 may be electrically connected to the first substrate interconnection patterns 120. For example, the tail portion of the first substrate interconnection pattern 120 may be provided to penetrate the first substrate insulating pattern 110 and may be coupled to a top surface of the outer pad 130. The outer pads 130 may be used as pads, to which outer terminals 150 are coupled. A width W1 of the outer pads 130 may be uniform, regardless of a position in a vertical direction. Here, the term ‘vertical direction’ may refer to a direction from the top surface of the outer pad 130 toward the bottom surface of the outer pad 130. The width W1 of the outer pads 130 may be equal or similar to a width W2 of the first substrate interconnection patterns 120. However, the present disclosure is not limited to this example. A thickness T1 of the outer pads 130 may be equal to or smaller than a thickness T2 of the first substrate interconnection patterns 120. The thickness T1 of the outer pads 130 may range from 5 μm to 20 μm. A distance P1 between the outer pads 130 may be equal to or smaller than a distance P2 between the first substrate interconnection patterns 120. The distance P1 between the outer pads 130 may range from 10 μm to 150 μm. However, the thickness T1 and the distance P1 of the outer pads 130 are not limited to the above ranges. The outer pads 130 may include a conductive material. For example, the outer pads 130 may be formed of or include at least one of metallic materials (e.g., copper (Cu)).

The substrate protection layer 140 may be provided on the bottom surface of the first substrate interconnection layer. The substrate protection layer 140 may cover the bottom surface of the first substrate interconnection layer and may expose the outer pads 130. For example, the top surfaces of the outer pads 130 may be exposed to the outside of the substrate protection layer 140 near a top surface of the substrate protection layer 140, and the bottom surfaces of the outer pads 130 may be exposed to the outside of the substrate protection layer 140 near a bottom surface of the substrate protection layer 140. In other words, the outer pads 130 may vertically penetrate the substrate protection layer 140. The top surfaces of the outer pads 130 and the top surface of the substrate protection layer 140 may be coplanar with each other, and the bottom surfaces of the outer pads 130 and the bottom surface of the substrate protection layer 140 may be coplanar with each other. The substrate protection layer 140 may include a material different from the first substrate insulating pattern 110. For example, the substrate protection layer 140 may include a molding member. In some implementations, the molding member may include an insulating polymer material (e.g., an epoxy molding compound (EMC) or an Ajinomoto build-up film (ABF)).

In some implementations, the outer pads 130 may not protrude to a region on the bottom surface of the substrate protection layer 140. In addition, the outer pads 130 may have a thickness that is equal to or smaller than the substrate interconnection patterns 120. That is, the pad layer PL may have a small thickness, and this may make it possible to reduce the size of the semiconductor package. Furthermore, the outer pad 130 may be provided to have a width and a distance that are equal or similar to those of substrate interconnection patterns 120. Thus, it may be possible to increase an integration density of the outer pads 130, which are used to connect the semiconductor package to an external device, and to reduce a planar size of the outer pad 130. That is, the semiconductor package may be provided to have a reduced size and an increased integration density.

Referring back to FIGS. 1 and 2, the pad layer PL may have a total thickness variation (TTV) of 0 or larger. In the present specification, the total thickness variation (TTV) may be defined as the largest variation in thickness of the substrate or wafer and may be calculated as the largest variation in thicknesses of the substrate or wafer measured at several positions of the substrate or wafer. The total thickness variation (TTV) of the pad layer PL may range from 0 μm to 10 μm. With regard to the shape of the pad layer PL, a top surface PLa of the pad layer PL may have a surface flatness that is different from a bottom surface PLb of the pad layer PL. For example, the surface flatness of the top surface PLa of the pad layer PL may be greater than the surface flatness of the bottom surface PLb of the pad layer PL. In some implementations, the top surface PLa of the pad layer PL may be substantially flat. In other words, the top surface of the substrate protection layer 140 and the top surfaces of the outer pads 130 may be substantially flat and may be located at substantially the same level. The bottom surface PLb of the pad layer PL may have an uneven shape. For example, the bottom surface of the substrate protection layer 140 and the bottom surfaces of the outer pads 130 may be bent or curved. In detail, the bottom surface PLb of the pad layer PL may have a wavy shape. For example, the bottom surface PLb may have a wavy shape, in which concave and convex (e.g., recessed and protruding) portions are repeated, where the concave or recessed portions are concavely curved in a direction toward an inner portion of the pad layer PL and the convex or protruding portions are convexly curved in a direction away from the pad layer PL. Here, a level difference between high and low points in the wavy structure of the bottom surface PLb (i.e., a height difference between the concave and convex portions) may range from 0 μm to 10 μm.

In some implementations, even when the bottom surface PLb of the pad layer PL has an uneven shape, the top surface PLa of the pad layer PL may have a flat shape. In other words, even when the pad layer PL has a large total thickness variation (TTV), the first substrate interconnection layer, which is disposed on the pad layer PL, may be provided to have a flat or planarized shape, and the conductive posts 310, which are provided on the first substrate interconnection layer, may be placed at substantially the same level. This may make it possible to improve the structural stability of the semiconductor package. The pad layer PL may have a finite value in the total thickness variation (TTV) while forming the first redistribution layer 100. This will be described in more detail with reference to a fabrication method to be described below.

Referring back to FIGS. 1 and 2, the outer terminals 150 may be provided on exposed bottom surfaces of the outer pads 130. The outer terminals 150 may include solder balls or solder bumps, and the semiconductor package may include solder balls or solder bumps, and the semiconductor package may be classified into a ball grid array (BGA) package, a fine ball-grid array (FBGA) package, or a land grid array (LGA) package, depending on the kind and arrangement of the outer terminals 150.

A bridge chip 200 may be disposed on the first redistribution layer 100. The bridge chip 200 may be disposed on a center region of the first redistribution layer 100. The bridge chip 200 may be in contact with a top surface of the first redistribution layer 100. In detail, the bridge chip 200 may be placed between some of the first substrate interconnection patterns 120 (e.g., the redistribution pads of the first redistribution layer 100), which are exposed from the first substrate insulating pattern 110. The bridge chip 200 may be attached to the top surface of the first substrate insulating pattern 110. The bridge chip 200 may have a front surface and a rear surface. Hereinafter, in the present specification, the front surface may be defined as a surface of a semiconductor chip, which is an active surface with integrated devices, and on which interconnection wires or pads are formed, and the rear surface may be defined as a surface that is opposite to the front surface of the semiconductor chip. The rear surface of the bridge chip 200 may face the first redistribution layer 100. That is, the bridge chip 200 may be disposed on the first redistribution layer 100 in a face up manner. The bridge chip 200 may be attached to the first redistribution layer 100 using an adhesive layer 202. For example, the adhesive layer 202 may be interposed between the bottom surface of the bridge chip 200 and the top surface of the first redistribution layer 100 (i.e., the top surface of the first substrate insulating pattern 110). The redistribution pads of the first redistribution layer 100 may not be provided below the bridge chip 200. The bridge chip 200 may include a bridge base layer 210 and a bridge interconnection layer 220.

The bridge base layer 210 may include a semiconductor substrate. For example, the bridge base layer 210 may be a semiconductor substrate (e.g., a semiconductor wafer). The bridge base layer 210 may be a silicon substrate, a silicon-on-insulator (SOI) substrate, a germanium (Ge) substrate, a germanium-on-insulator (GOI) substrate, a silicon-germanium (SiGe) substrate, a group III-V semiconductor substrate, or a substrate including an epitaxial film formed by a selective epitaxial growth (SEG) process. The bridge base layer 210 may be formed of or include at least one of silicon (Si), germanium (Ge), silicon-germanium (SiGe), gallium arsenic (GaAs), indium gallium arsenic (InGaAs), or aluminum gallium arsenic (AlGaAs).

The bridge interconnection layer 220 may be disposed on a top surface of the bridge base layer 210. For example, the bridge interconnection layer 220 may include a bridge insulating pattern 222 and a bridge interconnection pattern 224, which are formed on the top surface of the bridge base layer 210. The bridge interconnection layer 220 may further include a circuit pattern or a protection layer, if necessary.

The bridge insulating pattern 222 may include an insulating material. For example, the bridge insulating pattern 222 may be formed of or include at least one of silicon oxide (SiO), silicon nitride (SiN), silicon oxynitride (SiON), silicon carbonitride (SiCN), or insulating polymers. Alternatively, the bridge insulating pattern 222 may be formed of or include at least one of insulating polymers or photoimageable dielectric (PID) materials. Here, the PID materials may include at least one of photoimageable polyimide (PI), polybenzoxazole (PBO), phenol-based polymers, or benzocyclobutene-based polymers.

The bridge interconnection pattern 224 may be provided in the bridge insulating pattern 222. The bridge interconnection pattern 224 may be an element, which is used for an electric connection between semiconductor chips 500. The bridge interconnection pattern 224 may include a conductive material. For example, the bridge interconnection pattern 224 may be formed of or include at least one of conductive materials (e.g., copper (Cu) or aluminum (Al)).

FIG. 1 illustrates an example, in which the bridge insulating pattern 222 is a single layer, but the present disclosure is not limited to this example. In some implementations, the bridge insulating pattern 222 may have a plurality of insulating layers, and the bridge interconnection pattern 224 may be an interconnection pattern that is provided in the insulating layers.

The bridge chip 200 may include chip bumps 230, which are provided on a top surface of the bridge chip 200. The chip bumps 230 may be disposed on the top surface of the bridge chip 200 (i.e., the top surface of the bridge interconnection layer 220). For example, the chip bump 230 may protrude to a level that is higher than the top surface of the bridge chip 200. However, the present disclosure is not limited to this example, and the chip bump 230 may be a portion of the bridge interconnection pattern 224 and may be provided in the bridge insulating pattern 222. In this case, the chip bump 230 may be exposed to the outside of the bridge insulating pattern 222 near the top surface of the bridge insulating pattern 222. The chip bumps 230 may be connected to the bridge interconnection pattern 224 of the bridge interconnection layer 220. At least some of the chip bumps 230 may be electrically connected to others of the chip bumps 230 via the bridge interconnection pattern 224. FIG. 1 illustrates a portion of the bridge interconnection pattern 224, and the chip bumps 230 may not be disconnected from each other or may not be in an electrically-floated state.

FIG. 1 illustrates an example, in which the bridge chip 200 is provided for the electric connection between the semiconductor chips 500, but the present disclosure is not limited to this example. For example, a passive device chip, such as a resistor, a capacitor, or an inductor, may be provided in place of the bridge chip 200.

The conductive posts 310 may be disposed on the first redistribution layer 100. The conductive posts 310 may be disposed on an edge region of the first redistribution layer 100. For example, the conductive posts 310 may be horizontally spaced apart from the bridge chip 200. The conductive posts 310 may be disposed on the redistribution pads of the first redistribution layer 100. In detail, each of the conductive posts 310 may be in direct contact with a top surface of one of the first substrate interconnection patterns 120 in the first redistribution layer 100. The conductive posts 310 may be an element, which is used to connect the first redistribution layer 100 to a second redistribution layer 400 to be described below. That is, the conductive post 310 may correspond to a vertical connection terminal. The conductive post 310 may be a pillar-shaped pattern that is extended in a direction perpendicular to the top surface of the first redistribution layer 100. However, the present disclosure is not limited to this example, the conductive post 310 may have various shapes allowing for the vertical connection. A width of the conductive post 310 may be uniform in the vertical direction. For example, each of the conductive posts 310 may be a pillar-shaped pattern with a uniform width. Unlike that shown in FIG. 1, the width of the conductive posts 310 may decrease as a distance to the first redistribution layer 100 decreases. Top surfaces of the conductive posts 310 and the top surfaces of the chip bumps 230 of the bridge chip 200 may be located on the same plane. The conductive posts 310 may include a conductive material. For example, the conductive posts 310 may be formed of or include at least one of metallic materials (e.g., copper (Cu) or tungsten (W)).

Each of the conductive posts 310 may further include a seed layer 312, which is provided to enclose a side surface thereof. The seed layer 312 may be extended to a bottom surface of the conductive post 310. That is, the conductive posts 310 may be connected to the redistribution pads of the first redistribution layer 100 through the seed layers 312 that are interposed therebetween. The seed layers 312 may conformally cover the bottom and side surfaces of the conductive posts 310. A thickness of the seed layers 312 may range from 50 Å to 1000 Å. The seed layers 312 may include a metallic material, such as gold (Au).

A first mold layer 320 may be provided on the first redistribution layer 100. The first mold layer 320 on the first redistribution layer 100 may enclose the bridge chip 200 and the conductive posts 310. The first mold layer 320 may cover the bridge interconnection layer 220 of the bridge chip 200. Here, the first mold layer 320 may enclose the chip bumps 230 of the bridge chip 200. The chip bumps 230 may not be covered with the first mold layer 320 and may be exposed to the outside of the first mold layer 320 near a top surface of the first mold layer 320. The top surface of the first mold layer 320, the top surfaces of the chip bumps 230, and the top surfaces of the conductive posts 310 may be substantially flat and may be coplanar with each other. The first mold layer 320 may include a molding member. In some implementations, the molding member may include an insulating polymer material (e.g., an epoxy molding compound (EMC) or an Ajinomoto build-up film (ABF)).

The second redistribution layer 400 may be provided on the bridge chip 200, the conductive posts 310, and the first mold layer 320. The second redistribution layer 400 may be in direct contact with the top surfaces of the chip bumps 230 of the bridge chip 200, the top surfaces of the conductive posts 310, and the top surface of the first mold layer 320.

The second redistribution layer 400 may include one or more second substrate interconnection layers, which are stacked on top of each other. Each of the second substrate interconnection layers may include a second substrate insulating pattern 410 and second substrate interconnection patterns 420 in the second substrate insulating pattern 410. In the case where a plurality of second substrate interconnection layers are provided, the second substrate interconnection patterns 420 of one of the second substrate interconnection layers may be electrically connected to the second substrate interconnection patterns 420 of another second substrate interconnection layer adjacent thereto.

The second substrate insulating pattern 410 may be formed of or include at least one of insulating polymers or photoimageable polymers (e.g., photoimageable dielectric (PID) materials). For example, the photoimageable polymers may include at least one of photoimageable polyimide (PI), polybenzoxazole (PBO), phenol-based polymers, or benzocyclobutene-based polymers.

The second substrate interconnection patterns 420 may be provided on the second substrate insulating pattern 410. The second substrate interconnection patterns 420 on the second substrate insulating pattern 410 may be horizontally extended. The second substrate interconnection patterns 420 may be provided on a top surface of the second substrate insulating pattern 410. The second substrate interconnection pattern 420 may include a protruding portion that is extended to a level higher than the top surface of the second substrate insulating pattern 410. The second substrate interconnection patterns 420 on the second substrate insulating pattern 410 may be covered with another second substrate insulating pattern 410 which is disposed thereon. The second substrate interconnection patterns 420, which are provided in the uppermost one of the second substrate interconnection layers, may be used as substrate pads, to which the semiconductor chips 500 are coupled. As described above, the second substrate interconnection patterns 420 may be a pad portion or a wire portion of the second substrate interconnection layer. In other words, the second substrate interconnection patterns 420 may be an element for a horizontal redistribution in the second redistribution layer 400. The second substrate interconnection patterns 420 may include a conductive material. For example, the second substrate interconnection patterns 420 may be formed of or include at least one of metallic materials (e.g., copper (Cu)).

The second substrate interconnection patterns 420 may have a damascene structure. For example, the second substrate interconnection pattern 420 may include a via portion, which is protrudingly extended from a bottom surface thereof. The via portion may be an element, which is used to vertically connect the second substrate interconnection patterns 420 of adjacent ones of the second substrate interconnection layers to each other. For example, the via portion may be extended from a bottom surface of the second substrate interconnection pattern 420 to penetrate the second substrate insulating pattern 410 and may be coupled to a top surface of the second substrate interconnection pattern 420 of another second substrate interconnection layer thereunder. Alternatively, the via portion may be an element, which is used to connect the second substrate interconnection pattern 420 of the lowermost one of the second substrate interconnection layers to the conductive post 310 or to connect the second substrate interconnection pattern 420 of the lowermost one of the second substrate interconnection layers to the chip bump 230. For example, the via portion may be extended from the bottom surface of the second substrate interconnection pattern 420 to penetrate the lowermost one of the second substrate insulating patterns 410 and may be coupled to a top surface of the conductive post 310 or a top surface of the chip bump 230. In other words, the bridge chip 200 may be mounted on a bottom surface of the second redistribution layer 400 using the chip bumps 230. In other words, an upper portion of the second substrate interconnection pattern 420, which is placed on the second substrate insulating pattern 410, may be a head portion that is used as a horizontal interconnection line or a pad, and the via portion of the second substrate interconnection patterns 420 may be a tail portion. A width of the tail portion may be smaller than a width of the head portion. The width of the tail portion may decrease as a distance from the head portions of the second substrate interconnection patterns 420 increases. In other words, the tail portion may have a tapered shape. The second substrate interconnection patterns 420 may have the shape of the letter ‘T’.

Although not shown, second seed/barrier layers may be provided between the second substrate interconnection patterns 420 and the second substrate insulating pattern 410. Each of the second seed/barrier layers may cover a bottom surface of one of the second substrate interconnection patterns 420. In some implementations, the second seed/barrier layers may conformally cover the bottom surfaces of the second substrate interconnection patterns 420. The second seed/barrier layers may be provided to expose side surfaces of the second substrate interconnection patterns 420. Alternatively, each of the second seed/barrier layers may be provided to cover bottom and side surfaces of one of the second substrate interconnection patterns 420. In this case, the second seed/barrier layers may conformally cover the bottom and side surfaces of the second substrate interconnection patterns 420. A distance between the second substrate insulating pattern 410 and the second substrate interconnection patterns 420 (i.e., a thickness of the second seed/barrier layers) may range from 50 Å to 1000 Å. In the case where the second seed/barrier layers are used as a seed layer, the second seed/barrier layers may include a metallic material, such as gold (Au). In the case where the second seed/barrier layers are used as a barrier layer, the second seed/barrier layers may include a metallic material, such as titanium (Ti) and tantalum (Ta), or a metal nitride material, such as titanium nitride (TiN) and tantalum nitride (TaN). In some implementations, the second seed/barrier layers may not be provided.

The semiconductor chips 500 may be provided on the second redistribution layer 400. Each of the semiconductor chips 500 may include at least two portions, one of which is vertically overlapped with the bridge chip 200, and another of which is vertically overlapped with at least one of the conductive posts 310. However, the present disclosure is not limited to this example. The disposition of the semiconductor chips 500 may be variously changed depending on an interconnection layout of the second redistribution layer 400. The semiconductor chips 500 may include a chip base layer 510 and a chip interconnection layer 520.

The chip base layer 510 may include a semiconductor substrate. For example, the chip base layer 510 may be a semiconductor substrate, such as a semiconductor wafer. The chip base layer 510 may be a silicon substrate, a silicon-on-insulator (SOI) substrate, a germanium (Ge) substrate, a germanium-on-insulator (GOI) substrate, a silicon-germanium (SiGe) substrate, a group III-V semiconductor substrate, or a substrate including an epitaxial film formed by a selective epitaxial growth (SEG) process. The chip base layer 510 may be formed of or include at least one of silicon (Si), germanium (Ge), silicon-germanium (SiGe), gallium arsenic (GaAs), indium gallium arsenic (InGaAs), or aluminum gallium arsenic (AlGaAs). An integrated circuit may be provided on a bottom surface of the chip base layer 510. The integrated circuit may include a logic circuit or a memory circuit. That is, the semiconductor chips 500 may be a logic chip or a memory chip. However, the present disclosure is not limited to this example, and the semiconductor chips 500 may include a logic chip, a memory chip, a semiconductor chip with other integrated circuit, or a passive device. The integrated circuits, which are provided in the semiconductor chips 500, may be the same or different from each other. That is, the semiconductor chips 500 may be semiconductor chips of the same kind or of different kinds. A bottom surface of the semiconductor chip 500 may be an active surface, and a top surface of the semiconductor chip 500 may be an inactive surface. In other words, the semiconductor chips 500 may be disposed on the second redistribution layer 400 in a face down manner.

The chip interconnection layer 520 may be disposed on the bottom surface of the chip base layer 510. For example, the chip interconnection layer 520 may include a chip insulating pattern 522 and a chip interconnection pattern 524, which are formed on the bottom surface of the chip base layer 510. In some implementations, the chip interconnection layer 520 may further include a circuit pattern or a protection layer.

The chip insulating pattern 522 on the bottom surface of the chip base layer 510 may cover the integrated circuit. The chip insulating pattern 522 may include an insulating material. For example, the chip insulating pattern 522 may be formed of or include at least one of silicon oxide (SiO), silicon nitride (SiN), silicon oxynitride (SiON), silicon carbonitride (SiCN), or insulating polymers. Alternatively, the chip insulating pattern 522 may be formed of or include at least one of insulating polymers or photoimageable polymers (e.g., photoimageable dielectric (PID) materials). For example, the photoimageable polymers may include at least one of photoimageable polyimide (PI), polybenzoxazole (PBO), phenol-based polymers, or benzocyclobutene-based polymers.

The chip interconnection pattern 524 may be provided in the chip insulating pattern 522. The chip interconnection pattern 524 may be electrically connected to the integrated circuit, which is formed on the bottom surface of the chip base layer 510. The chip interconnection pattern 524 may include a conductive material. For example, the chip interconnection pattern 524 may be formed of or include copper (Cu) or aluminum (Al).

The semiconductor chips 500 may include chip pads 526, which are provided on bottom surfaces thereof. The chip pads 526 may be disposed on the bottom surfaces of the semiconductor chips 500 (i.e., the bottom surfaces of the chip interconnection layer 520). That is, the chip pads 526 may be exposed to the outside of the semiconductor chips 500 near the bottom surfaces of the semiconductor chips 500. The chip pads 526 may be electrically connected to the integrated circuit, which is formed on the bottom surface of the chip base layer 510, through the chip interconnection pattern 524 in the chip interconnection layer 520.

The semiconductor chips 500 may be mounted on the second redistribution layer 400. For example, the semiconductor chips 500 may be mounted on the second redistribution layer 400 in a flip chip manner. In detail, the semiconductor chips 500 may be electrically connected to the substrate pads of the second redistribution layer 400 through connection terminals 530. The connection terminals 530 may be provided between the chip pads 526 and the substrate pads of the second redistribution layer 400. The semiconductor chips 500 may be electrically connected to each other through the connection terminals 530, the second redistribution layer 400, and the bridge chip 200. The semiconductor chips 500 may be electrically connected to the first redistribution layer 100 through the connection terminals 530, the second redistribution layer 400, and the conductive posts 310. Since the semiconductor chips 500 are mounted using the connection terminals 530, the semiconductor chips 500 may be spaced apart from the top surface of the second redistribution layer 400.

A second mold layer 600 may be provided on the second redistribution layer 400. The second mold layer 600 on the second redistribution layer 400 may enclose the semiconductor chips 500. The second mold layer 600 may cover the semiconductor chips 500. In some implementations, the semiconductor chips 500 may have top surfaces that are exposed to the outside of the second mold layer 600 near a top surface of the second mold layer 600. The second mold layer 600 may fill a space between the semiconductor chips 500 and the second redistribution layer 400. Below the semiconductor chips 500, the second mold layer 600 may enclose the connection terminals 530. The second mold layer 600 may include a molding member. In some implementations, the molding member may include an insulating polymer material (e.g., an epoxy molding compound (EMC) or an Ajinomoto build-up film (ABF)).

Hereinafter, an element previously described with reference to FIGS. 1 to 5 may be identified by the same reference number without repeating an overlapping description thereof, for convenience in description. That is, technical features, which are different from those in the implementations of FIGS. 1 to 3, will be mainly described below.

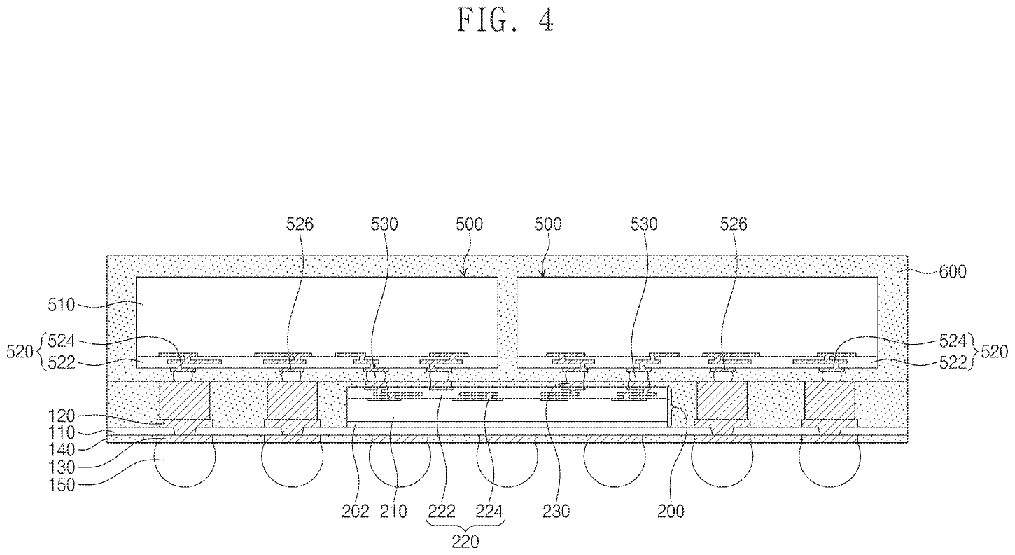

FIG. 4 is a sectional view illustrating an example of a semiconductor package.

Referring to FIG. 4, the semiconductor package does not include the second redistribution layer 400, unlike the implementations of FIGS. 1 to 3.

The bridge chip 200, the conductive posts 310, and the first mold layer 320 may be provided on the first redistribution layer 100. The top surface of the first mold layer 320, the top surfaces of the chip bumps 230, and the top surface of the conductive posts 310 may be substantially flat and may be coplanar with each other.

The semiconductor chips 500 may be mounted on the bridge chip 200, the conductive posts 310, and the first mold layer 320. For example, the semiconductor chips 500 may be mounted in a flip chip manner. In detail, each of the semiconductor chips 500 may be electrically connected to the conductive posts 310 and the chip bumps 230 of the bridge chip 200 through the connection terminals 530. The semiconductor chips 500 may be electrically connected to each other through the connection terminals 530 and the bridge chip 200. The semiconductor chips 500 may be electrically connected to the first redistribution layer 100 through the connection terminals 530 and the conductive posts 310.

The second mold layer 600 may be provided on the first mold layer 320. The second mold layer 600 on the first mold layer 320 may enclose the semiconductor chips 500. The second mold layer 600 may cover the semiconductor chips 500.

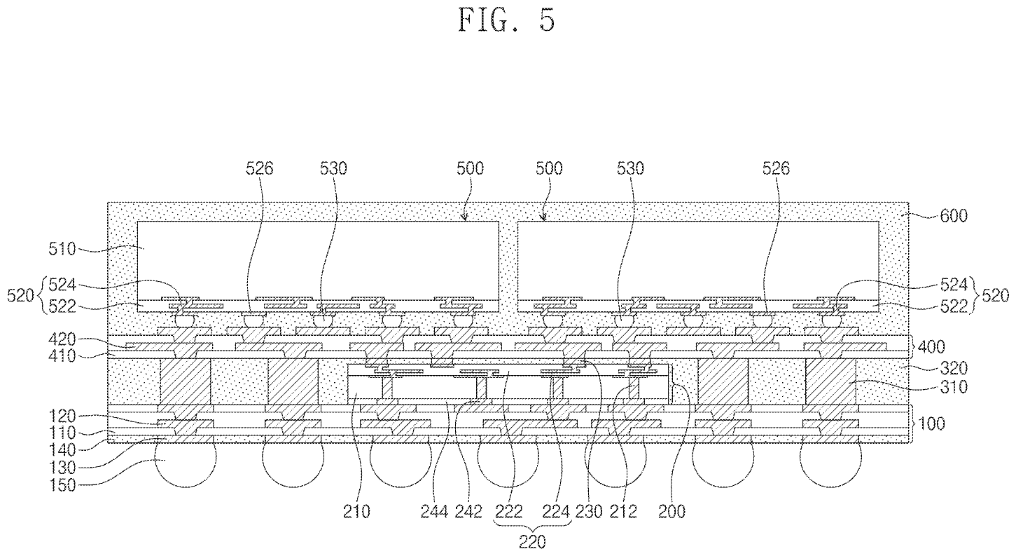

FIG. 5 is a sectional view illustrating an example of a semiconductor package.

Referring to FIG. 5, the bridge chip 200 further includes chip vias 212 and chip back-side pads 242.

The chip vias 212 may be provided to vertically penetrate the bridge base layer 210 and may be connected to the bridge interconnection layer 220. The chip vias 212 may be exposed to the outside of the bridge base layer 210 near an inactive surface of the bridge base layer 210 (i.e., the bottom surface of the bridge base layer 210). The chip vias 212 may include a conductive material. For example, the chip vias 212 may be formed of or include at least one of metallic materials (e.g., copper (Cu) or tungsten (W)).

The chip back-side pads 242 may be disposed on the bottom surface of the bridge base layer 210. Each of the chip back-side pads 242 on the bottom surface of the bridge base layer 210 may be connected to a corresponding one of the chip vias 212. The chip back-side pads 242 may include a conductive material. The chip back-side pads 242 may be formed of or include at least one of, for example, metallic materials (e.g., copper (Cu) or tungsten (W)).

A back-side protection layer 244 may be disposed on the bottom surface of the bridge base layer 210. The back-side protection layer 244 may cover the bottom surface of the bridge base layer 210. The back-side protection layer 244 may enclose the chip back-side pads 242. Here, a bottom surface of the back-side protection layer 244 and bottom surfaces of the chip back-side pads 242 may be substantially flat and may be coplanar with each other. The back-side protection layer 244 may include an insulating material. For example, the back-side protection layer 244 may be formed of or include at least one of silicon oxide (SiO), silicon nitride (SiN), or silicon oxynitride (SiON). In some implementations, the back-side protection layer 244 may not be provided.

The bridge chip 200 may be disposed on the first redistribution layer 100. The bridge chip 200 may be in contact with the top surface of the first redistribution layer 100. In detail, the chip back-side pads 242 and the back-side protection layer 244 of the bridge chip 200 may be in contact with the top surface of the first redistribution layer 100. Here, the first substrate interconnection patterns 120 of the first redistribution layer 100 may be connected to the chip back-side pads 242. Thus, the bridge chip 200 may be electrically connected to the first redistribution layer 100 through the chip vias 212 and the chip back-side pads 242.

The first redistribution layer 100 may further include additional first substrate insulating pattern 110, which are provided on the first substrate insulating pattern 110 to enclose the redistribution pads (i.e., the first substrate interconnection patterns 120). A top surface of the additional first substrate insulating pattern 110 and the top surfaces of the first substrate interconnection patterns 120 may be substantially flat and may be coplanar with each other. In this case, the additional first substrate insulating pattern 110 may be in direct contact with the back-side protection layer 244 of the bridge chip 200.

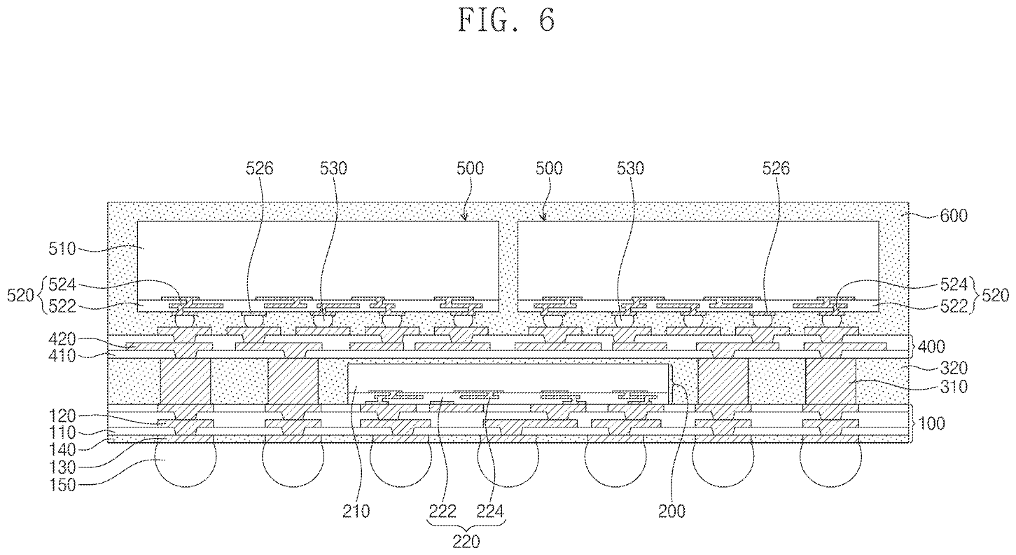

FIG. 6 is a sectional view illustrating an example of a semiconductor package.

Referring to FIG. 6, the bridge chip 200 is disposed on the first redistribution layer 100. The bridge chip 200 has a front surface and a rear surface. The front surface of the bridge chip 200 faces the first redistribution layer 100. That is, the bridge chip 200 is disposed on the first redistribution layer 100 in a face down manner. The bridge chip 200 includes the bridge base layer 210 and the bridge interconnection layer 220.

The bridge interconnection layer 220 may be disposed on a bottom surface of the bridge base layer 210. For example, the bridge interconnection layer 220 may include the bridge insulating pattern 222 and the bridge interconnection pattern 224, which are formed on the bottom surface of the bridge base layer 210.

The bridge chip 200 may be disposed on the first redistribution layer 100. The bridge chip 200 may be in contact with the top surface of the first redistribution layer 100. In detail, the bridge interconnection layer 220 of the bridge chip 200 may be in contact with the top surface of the first redistribution layer 100. Here, the first substrate interconnection pattern 120 of the first redistribution layer 100 may be connected to the bridge interconnection pattern 224 of the bridge interconnection layer 220. Thus, the bridge chip 200 may be electrically connected to the first redistribution layer 100.

The conductive posts 310 may be disposed on the first redistribution layer 100. The conductive posts 310 may be disposed on the edge region of the first redistribution layer 100. For example, the conductive posts 310 may be horizontally spaced apart from the bridge chip 200.

The first mold layer 320 may be provided on the first redistribution layer 100. The first mold layer 320 on the first redistribution layer 100 may enclose the bridge chip 200 and the conductive posts 310. The first mold layer 320 may cover the bridge chip 200. Accordingly, the bridge chip 200 may be exposed to the outside of the first mold layer 320 near a top surface of the first mold layer 320. Alternatively, the top surface of the bridge chip 200 (i.e., the rear surface of the bridge base layer 210) may be exposed to the outside of the first mold layer 320 near the top surface of the first mold layer 320.

The second redistribution layer 400 may be provided on the conductive posts 310 and the first mold layer 320. The second redistribution layer 400 may be in direct contact with the top surfaces of the conductive posts 310 and the top surface of the first mold layer 320. The second substrate interconnection patterns 420 of the second redistribution layer 400 may be connected to the conductive posts 310.

The semiconductor chips 500 may be mounted on the second redistribution layer 400. The semiconductor chips 500 may be electrically connected to the bridge chip 200 through the second redistribution layer 400, the conductive posts 310, and the first redistribution layer 100.

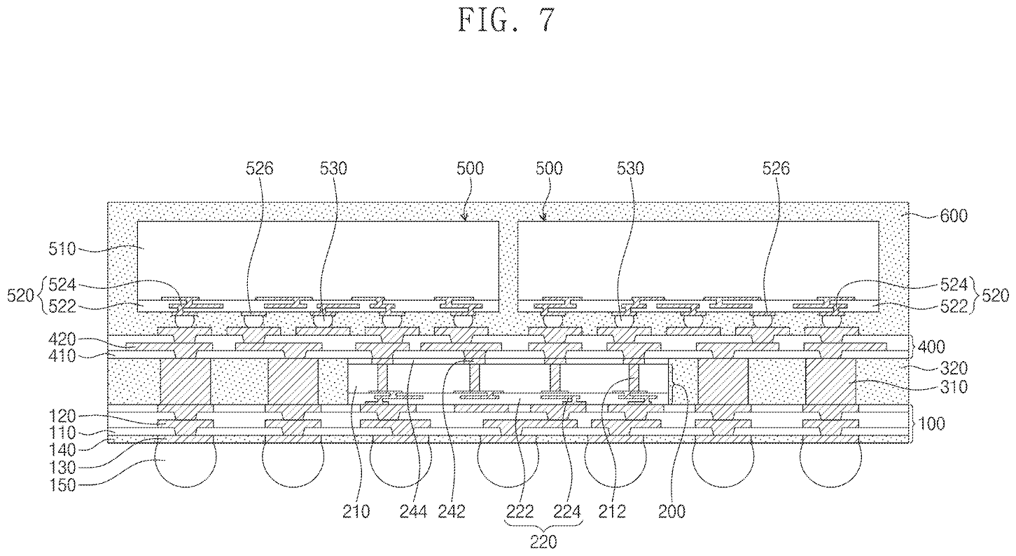

FIG. 7 is a sectional view illustrating an example of a semiconductor package.

Referring to FIG. 7, the bridge chip 200 of the semiconductor package further includes the chip vias 212 and the chip back-side pads 242, unlike the implementation of FIG. 6.

The chip vias 212 may be provided to vertically penetrate the bridge base layer 210 and may be connected to the bridge interconnection layer 220. The chip vias 212 may be exposed to the outside of the bridge base layer 210 near an inactive surface (i.e., the top surface) of the bridge base layer 210.

The chip back-side pads 242 may be disposed on the top surface of the bridge base layer 210. Each of the chip back-side pads 242 on the top surface of the bridge base layer 210 may be connected to a corresponding one of the chip vias 212.

The back-side protection layer 244 may be disposed on the top surface of the bridge base layer 210. The back-side protection layer 244 may cover the top surface of the bridge base layer 210. The back-side protection layer 244 may enclose the chip back-side pads 242. Here, a top surface of the back-side protection layer 244 and top surfaces of the chip back-side pads 242 may be substantially flat and may be coplanar with each other.

The first mold layer 320 may be provided on the first redistribution layer 100. The first mold layer 320 on the first redistribution layer 100 may enclose the bridge chip 200 and the conductive posts 310. The top surface of the bridge chip 200 may be exposed to the outside of the first mold layer 320 near the top surface of the first mold layer 320.

The second redistribution layer 400 may be provided on the bridge chip 200, the conductive posts 310, and the first mold layer 320. The second redistribution layer 400 may be in direct contact with the top surface of the bridge chip 200, the top surfaces of the conductive posts 310, and the top surface of the first mold layer 320. The second substrate interconnection patterns 420 of the second redistribution layer 400 may be connected to the chip back-side pads 242 of the bridge chip 200 and the conductive posts 310.

The semiconductor chips 500 may be mounted on the second redistribution layer 400. The semiconductor chips 500 may be electrically connected to the first redistribution layer 100 through the second redistribution layer 400 and the conductive posts 310 or may be electrically connected to the first redistribution layer 100 through the second redistribution layer 400 and the bridge chip 200. The semiconductor chips 500 may be electrically connected to each other through the second redistribution layer 400 and the bridge chip 200.

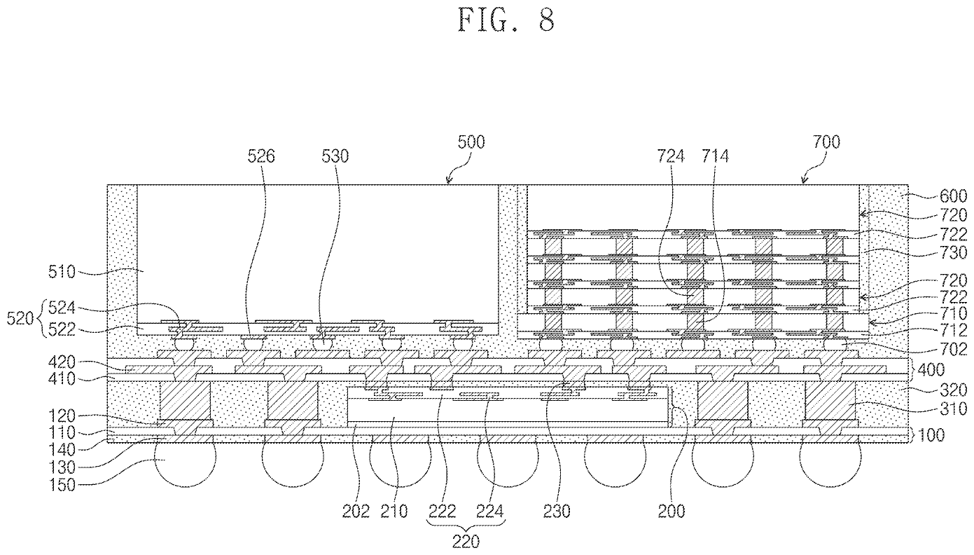

FIG. 8 is a sectional view illustrating an example of a semiconductor package.

Referring to FIG. 8, a semiconductor package includes a chip stack 700, which is provided in place of one of the semiconductor chips 500. Hereinafter, the semiconductor chip 500, which is directly mounted on the second redistribution layer 400, will be referred to as a first semiconductor chip 500.

The first semiconductor chip 500 may include a logic circuit. In other words, the first semiconductor chip 500 may be a logic chip. As an example, the first semiconductor chip 500 may include a graphic processing unit.

The chip stack 700 may be disposed on the second redistribution layer 400. The chip stack 700 may be spaced apart from the first semiconductor chip 500. A thickness of the first semiconductor chip 500 may be larger than thicknesses of the semiconductor chips 710 and 720 of the chip stack 700. A top surface of the chip stack 700 may be located at a level, which is equal to or higher than a top surface of the first semiconductor chip 500.

The chip stack 700 may include a base substrate, second semiconductor chips 720 stacked on the base substrate, and a mold layer 730 enclosing the second semiconductor chips 720. Hereinafter, the structure of the chip stack 700 will be described in more detail below.

The base substrate may be the base semiconductor chip 710. For example, the base substrate may be a wafer-level semiconductor substrate that is formed of a semiconductor material (e.g., silicon (Si)). Hereinafter, the base semiconductor chip 710 may be the same element as the base substrate, and the base semiconductor chip and the base substrate may be identified using the same reference number.

The base semiconductor chip 710 may include a base circuit layer 712 and base penetration electrodes 714. The base circuit layer 712 may be provided on a bottom surface of the base semiconductor chip 710. The base circuit layer 712 may include an integrated circuit. For example, the base circuit layer 712 may be a memory circuit. That is, the base semiconductor chip 710 may be one of memory chips, such as DRAM, SRAM, MRAM and FLASH memory chips. Alternatively, the base semiconductor chip 710 may be a logic chip. The base penetration electrodes 714 may penetrate the base semiconductor chip 710 in a direction perpendicular to the top surface of the second redistribution layer 400. The base penetration electrodes 714 and the base circuit layer 712 may be electrically connected to each other. The bottom surface of the base semiconductor chip 710 may be an active surface. In some implementations, the base substrate may be an interconnection substrate which does not include the base semiconductor chip 710.

The second semiconductor chip 720 may be mounted on the base semiconductor chip 710. That is, the second semiconductor chip 720 and the base semiconductor chip 710 may form a chip-on-wafer (COW) structure. A width of the second semiconductor chip 720 may be smaller than a width of the base semiconductor chip 710.

The second semiconductor chip 720 may include a second circuit layer 722 and chip penetration electrodes 724. The second circuit layer 722 may include a memory circuit. In other words, the second semiconductor chip 720 may be one of memory chips, such as DRAM, SRAM, MRAM and FLASH memory chips. The second circuit layer 722 may include the same circuit as the base circuit layer 712, but the present disclosure is not limited to this example. The chip penetration electrodes 724 may penetrate the second semiconductor chip 720 in a direction perpendicular to the top surface of the second redistribution layer 400. The chip penetration electrodes 724 and the second circuit layer 722 may be electrically connected to each other. A bottom surface of the second semiconductor chip 720 may be an active surface.

The second semiconductor chip 720 may be bonded to the base semiconductor chip 710. For example, pads of the second circuit layer 722 of the second semiconductor chip 720 may be in contact with top surfaces of the base penetration electrodes 714, which are exposed to the outside of the base semiconductor chip 710 near a top surface of the base semiconductor chip 710. Alternatively, the second semiconductor chip 720 may be mounted on the top surfaces of the base penetration electrodes 714 using terminals, which are provided on the pads of the second circuit layer 722.

In some implementations, a plurality of second semiconductor chips 720 may be provided. For example, a plurality of second semiconductor chips 720 may be stacked on the base semiconductor chip 710. In some implementations, the number of the stacked second semiconductor chips 720 may range from 4 to 32. Here, the uppermost one of the second semiconductor chips 720 may not include the chip penetration electrodes 724. In addition, the uppermost one of the second semiconductor chips 720 may have a thickness that is larger than that of the second semiconductor chips 720 thereunder.

The second semiconductor chips 720, which are adjacent to each other, may be bonded to each other. For example, pads of the second circuit layer 722 in each of the second semiconductor chips 720 may be in contact with top surfaces of the chip penetration electrodes 724, which are exposed to the outside of the second semiconductor chip 720 near a top surface of the second semiconductor chip 720 thereunder. Alternatively, the second semiconductor chips 720 may be mounted on the top surfaces of the chip penetration electrodes 724 using terminals, which are provided on the pads of the second circuit layer 722.

The mold layer 730 may be disposed on the top surface of the base semiconductor chip 710. The mold layer 730 may cover the base semiconductor chip 710 and may enclose the second semiconductor chips 720. A top surface of the mold layer 730 may be coplanar with a top surface of the uppermost one of the second semiconductor chips 720, and the uppermost one of the second semiconductor chips 720 may be exposed from the mold layer 730. The mold layer 730 may include an insulating polymer material (e.g., an epoxy molding compound (EMC)).

The chip stack 700 may be provided to have the afore-described structure.

Connection terminals 702 may be provided on the bottom surface of the chip stack 700 (i.e., the bottom surface of the base circuit layer 712). The chip stack 700 may be coupled to the second redistribution layer 400 through the connection terminals 702.

The second mold layer 600 may be provided on the second redistribution layer 400. The second mold layer 600 may cover the top surface of the second redistribution layer 400. The second mold layer 600 may enclose the first semiconductor chip 500 and the chip stack 700. The top surface of the second mold layer 600 may be located at the same level as the top surface of the chip stack 700.

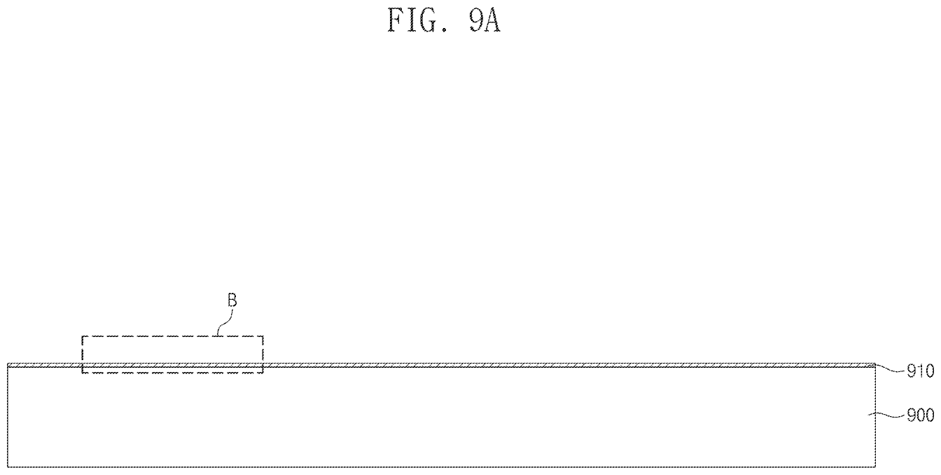

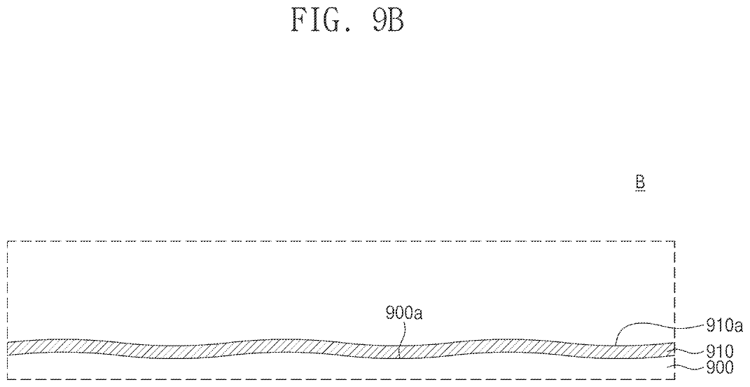

FIGS. 9A, 10A, 11A, 12A, 13A, 14A, 15A, 16A, and 17 are sectional views illustrating an example of a method of fabricating a semiconductor package. FIGS. 9B, 10B, 11B, 12B, 13B, 14B, 15B, and 16B are example enlarged sectional views illustrating portions ‘B’ of FIGS. 9A, 10A, 11A, 12A, 13A, 14A, 15A, and 16A.

Referring to FIGS. 9A and 9B, a carrier substrate 900 may be provided. The carrier substrate 900 may be an insulating substrate including at least one of organic insulating materials or polymer materials.

In the case where the carrier substrate 900 includes the organic insulating materials or polymer materials, the total thickness variation (TTV) property or the surface flatness property of the carrier substrate 900 may be deteriorated as an area of the carrier substrate 900 increases. For example, the carrier substrate 900 may have an uneven shape. For example, a top surface of the carrier substrate 900 may have a wavy shape, and a bottom surface of the carrier substrate 900 may have a wavy shape. In some implementations, each of the top and bottom surfaces of the carrier substrate 900 may have a wavy shape, in which concave and convex (i.e., recessed and protruding) portions are repeated, where the concave or recessed portions are concavely curved in a direction toward an inner portion of the carrier substrate 900 and the convex or protruding portions are convexly curved in a direction away from the carrier substrate 900. Here, in the top and bottom surfaces of the carrier substrate 900, a level difference between high and low points in the wavy structure (i.e., a height difference between the concave and convex portions) may range from 10 μm to 500 μm. The total thickness variation (TTV) of the carrier substrate 900 may range from 10 μm to 500 μm.

The carrier substrate 900 may further include a seed layer 910, which is provided on the top surface of the carrier substrate 900. As an example, the seed layer 910 may include a metallic material, such as gold (Au). In the case of the seed layer 910 that is formed on the top surface of the carrier substrate 900, the surface shape of the top surface of the carrier substrate 900 may be copied to the seed layer 910. That is, the seed layer 910 may have an uneven shape, and a top surface 910a of the seed layer 910 may have a wavy shape.

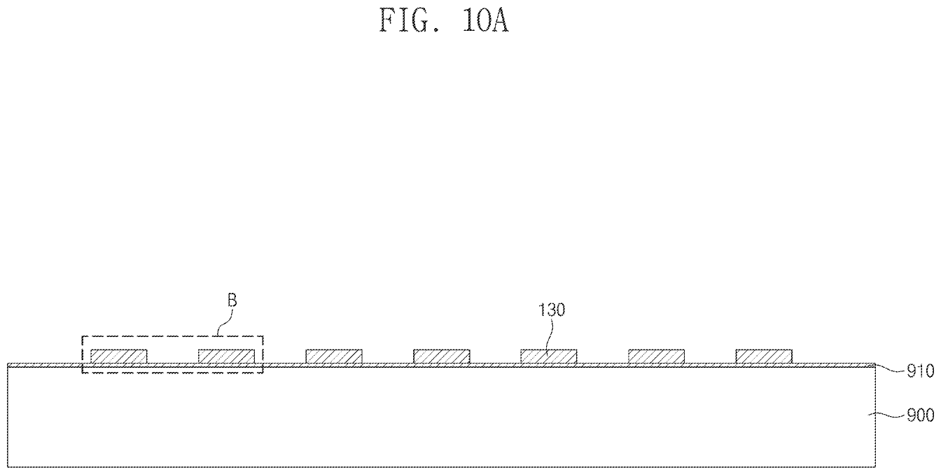

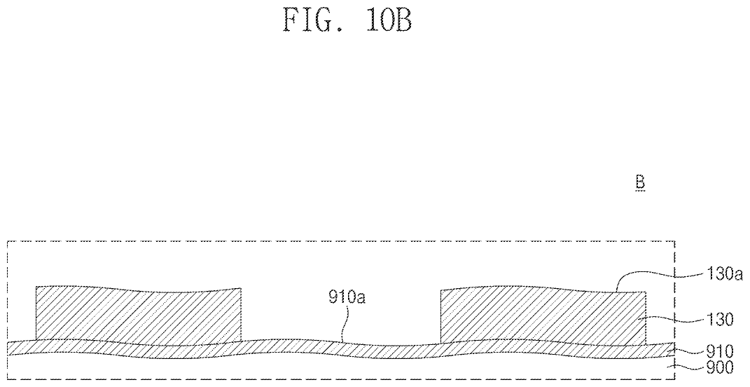

Referring to FIGS. 10A and 10B, the outer pads 130 may be formed. In detail, a sacrificial layer may be formed by coating the carrier substrate 900 with a photoimageable material. The exposing and developing processes may be performed on the sacrificial layer to define regions, in which the outer pads 130 are formed, and to form openings exposing the top surface 910a of the seed layer 910. The openings, which are formed by the photo-lithography process, may have a uniform width in a vertical direction. The outer pads 130 may be formed by a plating process using the seed layer 910, which is exposed through the openings. Thus, the outer pads 130 may have a uniform width in the vertical direction.

In some implementations, the outer pads 130, to which the outer terminals 150 (e.g., see FIG. 1) for mounting the semiconductor package are attached, may be formed through a photo-lithography process. Accordingly, it may be possible to easily reduce the width or distance of the outer pad 130. In other words, the semiconductor package may be fabricated to have a reduced size.

The surface shape of the top surface 910a of the seed layer 910 may be copied to the outer pads 130. For example, the outer pads 130 may be formed to have an uneven shape. Thus, top surfaces 130a of the outer pads 130 may be formed to have an uneven shape. In some implementations, the outer pads 130 may have top surfaces located at different levels, depending on a position on the top surface 910a of the seed layer 910. For example, the top surfaces of the outer pads 130, which are formed on the concave or recessed portion of the top surface 910a of the seed layer 910, may be located at a level lower than the top surfaces of the outer pads 130, which are formed on the concave or protruding portion of the top surface 910a of the seed layer 910.

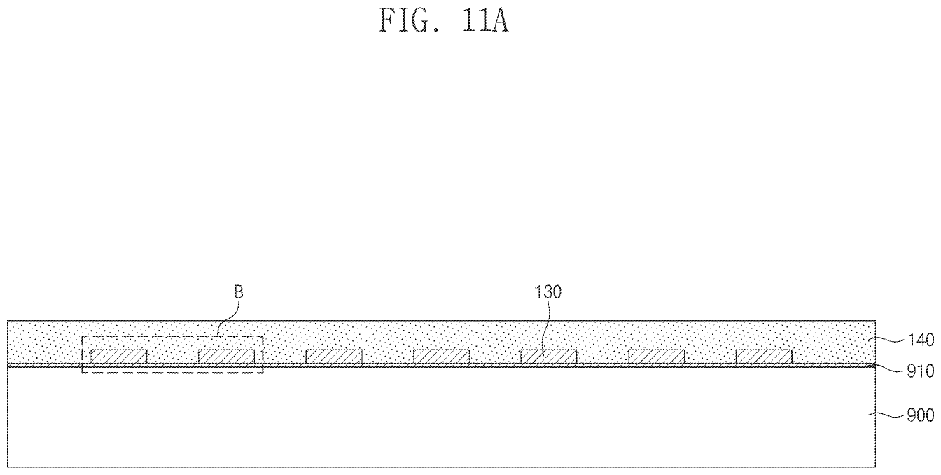

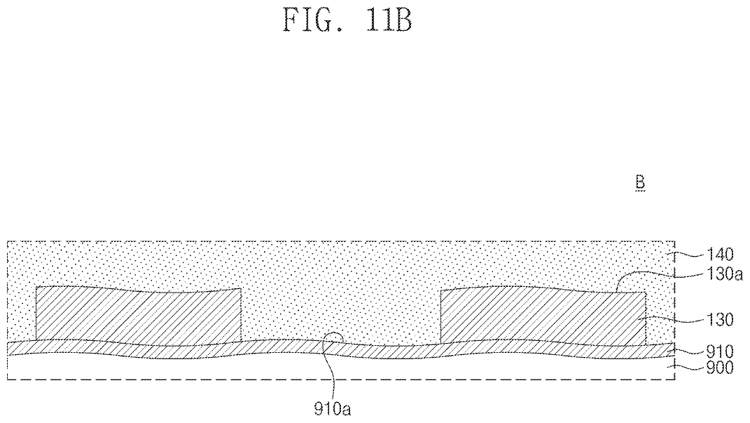

Referring to FIGS. 11A and 11B, the substrate protection layer 140 may be formed on the carrier substrate 900. For example, the substrate protection layer 140 may be formed by coating an insulating material on the seed layer 910 to cover the outer pads 130. In some implementations, a curing process may be performed on the insulating material. The insulating material may be chosen to allow for a grinding or polishing process. The material may include an insulating polymer material (e.g., an epoxy molding compound (EMC) or an Ajinomoto build-up film (ABF)). The outer pads 130 on the carrier substrate 900 may be buried in the substrate protection layer 140.

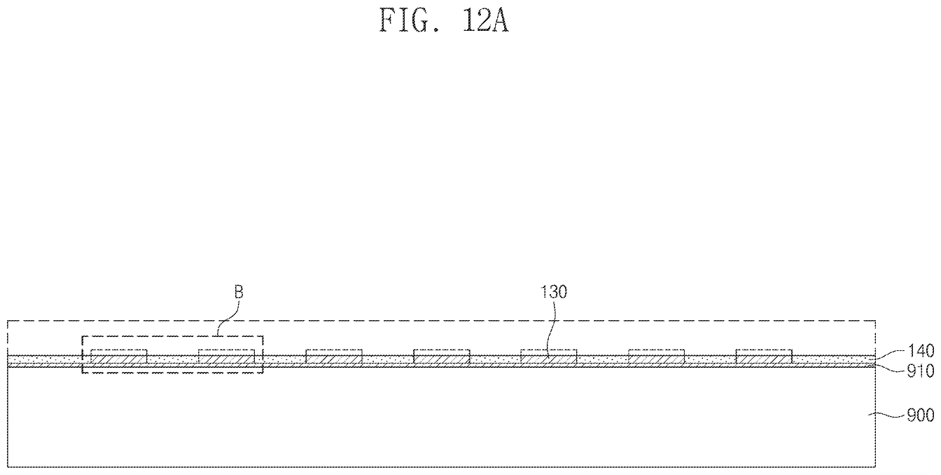

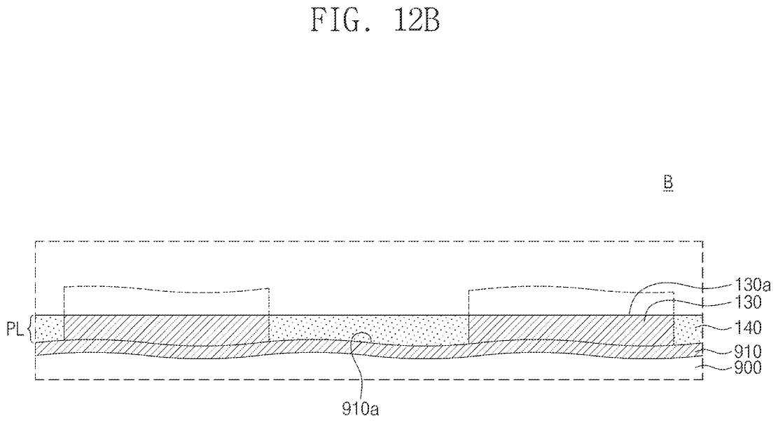

Referring to FIGS. 12A and 12B, a first planarization process may be performed on the substrate protection layer 140. For example, the first planarization process may include a chemical mechanical polishing (CMP) process. The first planarization process may be performed to expose the top surfaces of the outer pads 130. The first planarization process may be further performed, after the exposing of the top surfaces of the outer pads 130. For example, the first planarization process may be performed to effectively reduce the thickness of the outer pads 130. The thickness T1 of the outer pads 130 may range from 5 μm to 20 μm. The pad layer PL may be formed by the first planarization process. The top surface of the substrate protection layer 140 and the top surfaces 130a of the outer pads 130 may be coplanar with each other, after the first planarization process. The top surface of the substrate protection layer 140 and the top surfaces 130a of the outer pads 130 may be substantially flat. A total thickness variation (TTV) of the pad layer PL may range from 0 μm to 10 μm.

In some implementations, a first planarization process may be performed on the pad layer PL. Thus, even when, owing to an uneven shape of the carrier substrate 900, the outer pads 130 are formed to have an uneven top surface or the top surfaces of the outer pads 130 are formed at different levels, the pad layer PL may be formed to have a flat top surface. That is, the top surface 130a of each of the outer pads 130 may be formed to be flat, and moreover, the top surfaces 130a of the outer pads 130 may be formed at substantially the same level. As a result, when a back-end process is performed on the pad layer PL, it may be possible to reduce a process error or failure, which may be caused by the uneven surface or the variation in thickness. Furthermore, the first planarization process may enable the pad layer PL to have a sufficiently small thickness, and in this case, the semiconductor package may be formed to have a reduced size.

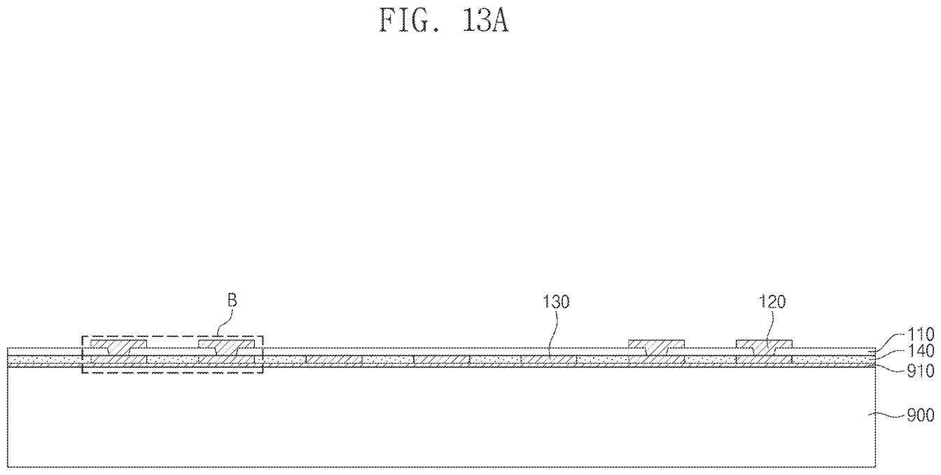

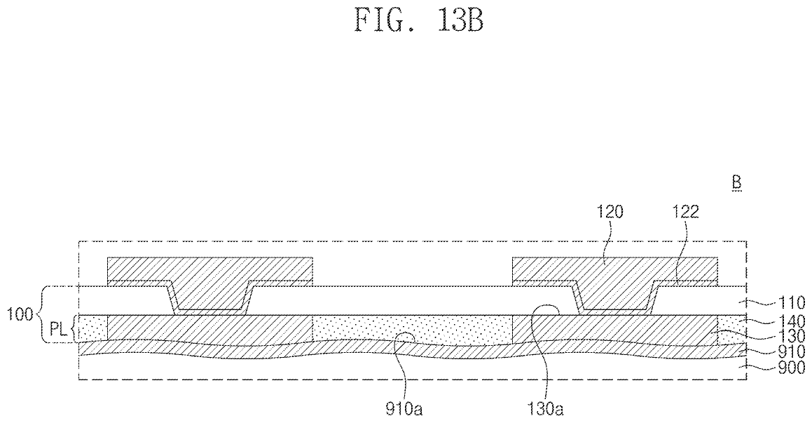

Referring to FIGS. 13A and 13B, the first substrate insulating pattern 110 may be formed on the substrate protection layer 140. The first substrate insulating pattern 110 may be formed using a deposition process or a coating process. The first substrate insulating pattern 110 may cover the substrate protection layer 140 and the outer pads 130. The first substrate interconnection patterns 120 may be formed on the first substrate insulating pattern 110. In some implementations, the first substrate insulating pattern 110 may be patterned to form openings exposing the outer pads 130, a seed layer may be formed to conformally cover the top surface of the first substrate insulating pattern 110 and inner surfaces of the openings, a plating process using the seed layer may be performed to form a conductive layer covering the first substrate insulating pattern 110 and filling the openings, and the conductive layer and the seed layer may be patterned to form the first substrate interconnection patterns 120 and the first seed/barrier layers 122. A first substrate interconnection layer, which is formed as a result of the above process, may include the first substrate insulating pattern 110, which is provided on the substrate protection layer 140 and the outer pads 130, and the first substrate interconnection patterns 120, which is provided in the first substrate insulating pattern 110. The pad layer PL and the first substrate interconnection layer may constitute the first redistribution layer 100.

Since the top surfaces 130a of the outer pads 130 are flat and are located at the same level, the top surfaces of the first substrate interconnection patterns 120 may be formed at substantially the same level.

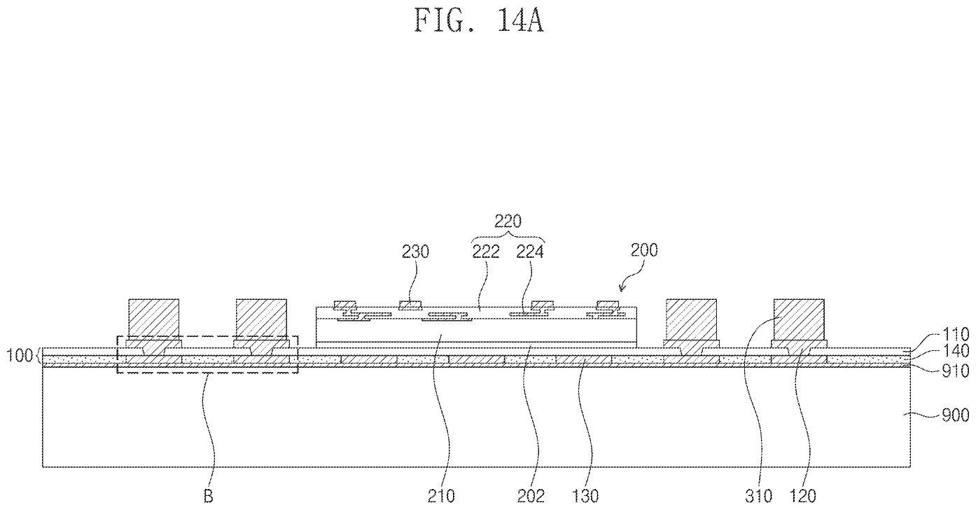

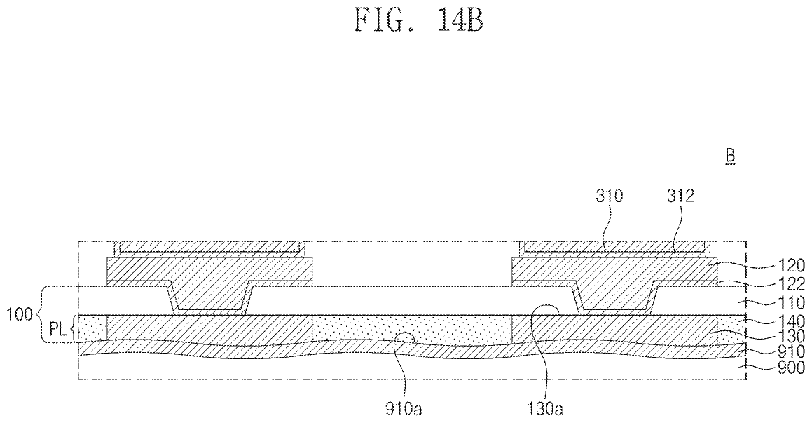

Referring to FIGS. 14A and 14B, the conductive posts 310 may be formed. In detail, a sacrificial layer may be formed on the first redistribution layer 100. The sacrificial layer may cover the top surface of the first redistribution layer 100. The sacrificial layer may be patterned to form holes exposing the substrate pads of the first redistribution layer 100 (i.e., some of the first substrate interconnection patterns 120). Next, the conductive posts 310 may be formed by filling the holes with a conductive material. For example, a seed layer may be formed to conformally cover a top surface of the sacrificial layer and inner surfaces of the holes, and a plating process using the seed layer may be performed to form the conductive posts 310 filling the holes. Alternatively, the conductive posts 310 may be formed by a plating process using top surfaces of the first substrate interconnection patterns 120, which are exposed through the holes, as a seed. Next, the sacrificial layer may be removed.

Since the top surfaces of the first substrate interconnection patterns 120 are formed at substantially the same level, top surfaces of the conductive posts 310 may be formed at substantially the same level.

The bridge chip 200 may be attached to the first redistribution layer 100. The bridge chip 200 may be provided to have substantially the same features as described with reference to FIGS. 1 to 8. The bridge chip 200 may be attached to the first redistribution layer 100 using the adhesive layer 202.

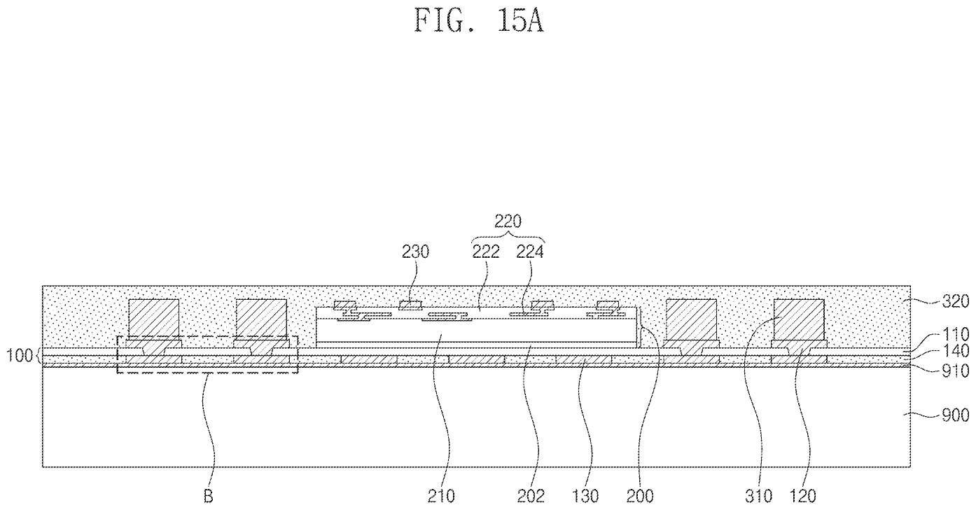

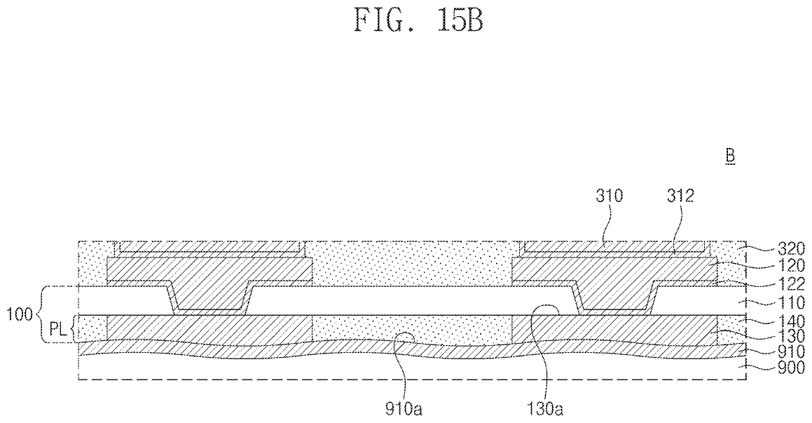

Referring to FIGS. 15A and 15B, the first mold layer 320 may be formed on the first redistribution layer 100. For example, an insulating layer may be coated on the first redistribution layer 100 to cover the bridge chip 200 and the conductive posts 310 and may be cured to form the first mold layer 320. The bridge chip 200 and the conductive posts 310 on the first redistribution layer 100 may be buried in the first mold layer 320. The first mold layer 320 may include a molding member. In some implementations, the molding member may include an insulating polymer material (e.g., an epoxy molding compound (EMC) or an Ajinomoto build-up film (ABF)).

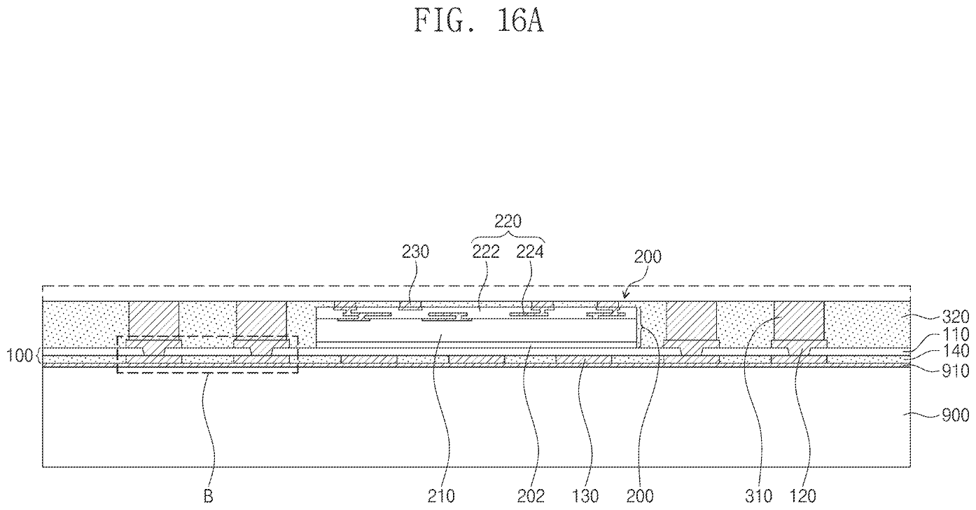

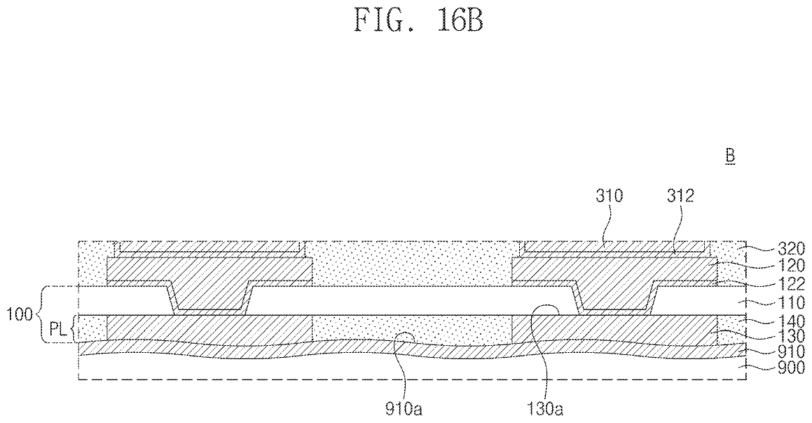

Referring to FIGS. 16A and 16B, a second planarization process may be performed on the first mold layer 320. For example, the second planarization process may include a chemical mechanical polishing (CMP) process. The second planarization process may be performed to expose top surfaces of the conductive posts 310 and top surfaces of the chip bumps 230 of the bridge chip 200. The top surfaces of the conductive posts 310, the top surface of the first mold layer 320, and the top surfaces of the chip bumps 230 may be coplanar with each other, after the second planarization process. In some implementations, the top surfaces of the conductive posts 310, the top surface of the first mold layer 320, and the top surfaces of the chip bumps 230 may be substantially flat.

If the top surface of the pad layer PL has an uneven shape, the surface shape of the top surface of the pad layer PL may be copied to the first substrate interconnection layer, which is formed on the pad layer PL. Accordingly, the top surfaces of the conductive posts 310, which are formed on the pad layer PL and the first substrate interconnection layer, may be formed at different levels or may have an uneven shape. In this case, some of the conductive posts 310 may not be exposed from the top surface of the first mold layer 320 and may be buried in the first mold layer 320, in the second planarization process. The not-opened ones of the conductive posts 310 may not be electrically connected to the second redistribution layer 400, which is formed on the first mold layer 320; that is, there may be an electrical disconnection failure.

In some implementations, the substrate protection layer 140 may be formed using a molding member, after the formation of the outer pads 130. Thus, a first planarization process may be performed on the outer pads 130 and the substrate protection layer 140 to planarize the top surface of the pad layer PL. The first substrate interconnection layer and the conductive posts 310, which are formed in a back-end process, may be formed to have flat top surfaces, and the top surfaces of the conductive posts 310 may be formed at the same level. Thus, when the second planarization process is formed on the first mold layer 320, the top surfaces of the conductive posts 310 may be exposed at substantially the same time. That is, it may be possible to reduce a failure, which may be caused in a back-end process by the shape of the carrier substrate 900 or the pad layer PL.

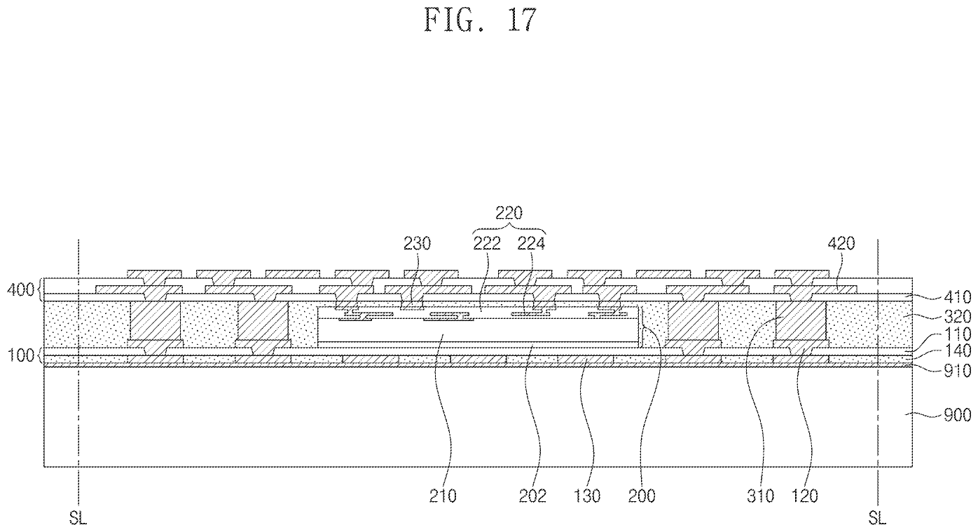

Referring to FIG. 17, the second substrate insulating pattern 410 may be formed on the first mold layer 320. The second substrate insulating pattern 410 may be formed using a deposition process or a coating process. The second substrate insulating pattern 410 may cover the conductive posts 310, the first mold layer 320, and the chip bumps 230. The second substrate interconnection patterns 420 may be formed on the second substrate insulating pattern 410. For example, the second substrate insulating pattern 410 may be patterned to form openings exposing the conductive posts 310 and the chip bumps 230, a seed layer may be formed to conformally cover the top surface of the second substrate insulating pattern 410 and inner surfaces of the openings, a plating process using the seed layer may be performed to form a conductive layer covering the second substrate insulating pattern 410 and filling the openings, and then, the conductive layer may be patterned to form the second substrate interconnection patterns 420.

A second substrate interconnection layer, which is formed as a result of the above process, may include the second substrate insulating pattern 410, which is formed on the first mold layer 320, and the second substrate interconnection pattern 420, which is formed in the second substrate insulating pattern 410. The process of forming the second substrate interconnection layer may be repeatedly performed to form the second redistribution layer 400. The second substrate interconnection pattern 420, which is provided in the uppermost one of the second substrate interconnection layers, may be used as substrate pads, on which the semiconductor chips 500 are mounted.

Thereafter, a singulation process may be performed on the carrier substrate 900 along a sawing line SL. For example, the second redistribution layer 400, the first mold layer 320, and the first redistribution layer 100 may be sequentially cut by the singulation process. Here, the sawing line SL may be horizontally spaced apart from the bridge chip 200 and the conductive posts 310, and the bridge chip 200 and the conductive posts 310 may not be cut by the singulation process.

Referring back to FIG. 1, the semiconductor chips 500 may be mounted on the second redistribution layer 400. The semiconductor chips 500 may be mounted in a flip chip manner.

The carrier substrate 900 may be removed. For example, the carrier substrate 900 and the seed layer 910 of the carrier substrate 900 may be removed to expose a bottom surface of the first redistribution layer 100.

The outer terminals 150 may be provided on the exposed bottom surface of the first redistribution layer 100 and may be coupled to the outer pads 130. The outer terminals 150 may include solder balls or solder bumps.

In some implementations, in a semiconductor package, an outer pad may be provided to have a thickness that is equal or similar to that of a substrate interconnection pattern. That is, a pad layer may be provided to have a small thickness, and this may make it possible to reduce the size of the semiconductor package. Furthermore, the outer pad may be provided to have a width and a distance that are equal or similar to those of the substrate interconnection pattern. Thus, it may be possible to increase an integration density of the outer pads, which are used to connect the semiconductor package to an external device, and to reduce a planar size of the outer pad. That is, the semiconductor package may be provided to have a reduced size and an increased integration density.

Even when the pad layer has an uneven shape, at least a top surface of the pad layer may be flat. A substrate interconnection layer disposed on the pad layer may be flat, and conductive posts, which are provided on the substrate interconnection layer, may be located at substantially the same level. This may make it possible to improve the structural stability of the semiconductor package.

In some implementations, in a method of fabricating a semiconductor package, a planarization process may be performed to planarize the top surface of the pad layer. The substrate interconnection layer and the conductive posts, which are formed through a back-end process, may be formed to have flat top surfaces, and the top surfaces of the conductive posts may be formed at substantially the same level. Thus, top surfaces of the conductive posts may be exposed at substantially the same time when the planarization process is performed on a mold layer. That is, it may be possible to reduce a failure, which may be caused by the shape of a carrier substrate or the pad layer in the back-end process.

While this specification contains many specific implementation details, these should not be construed as limitations on the scope of what may be claimed, but rather as descriptions of features that may be specific to particular implementations of particular inventions. Certain features that are described in this specification in the context of separate implementations can also be implemented in combination in a single implementation. Conversely, various features that are described in the context of a single implementation can also be implemented in multiple implementations separately or in any suitable subcombination. Moreover, although features may be described above as acting in certain combinations and even initially be claimed as such, one or more features from a claimed combination can in some cases be excised from the combination, and the claimed combination may be directed to a subcombination or variation of a subcombination.

While example implementations of the present disclosure have been particularly shown and described, it will be understood by one of ordinary skill in the art that variations in form and detail may be made therein without departing from the spirit and scope of the attached claims.

1. A semiconductor package comprising:
a first redistribution layer;
a bridge chip attached to a top surface of the first redistribution layer;
a mold layer on the first redistribution layer, the mold layer enclosing the bridge chip;
a second redistribution layer disposed on the mold layer;
a conductive post extending through the mold layer vertically and connecting the first redistribution layer and the second redistribution layer; and
a first semiconductor chip mounted on the second redistribution layer,
wherein the first redistribution layer comprises:
a pad layer; and
an interconnection layer disposed on the pad layer,
wherein the pad layer comprises:
a first insulating layer; and
a plurality of pads in the first insulating layer,
wherein a plurality of top surfaces of the plurality of pads are exposed to an outside of the first insulating layer near a top surface of the first insulating layer,
wherein a plurality of bottom surfaces of the plurality of pads are exposed to the outside of the first insulating layer near a bottom surface of the first insulating layer, and
wherein a surface flatness of a top surface of the pad layer is greater than a surface flatness of a bottom surface of the pad layer.

2. The semiconductor package of claim 1, wherein each pad of the plurality of pads has a uniform width in a vertical direction.

3. The semiconductor package of claim 1, wherein a total thickness variation (TTV) of the pad layer ranges from 0 μm to 10 μm.

4. The semiconductor package of claim 1, wherein the interconnection layer comprises:
a second insulating layer covering the first insulating layer and the plurality of pads; and
an interconnection pattern that is disposed on the second insulating layer, that extends through the second insulating layer, and that is coupled to the plurality of pads.

5. The semiconductor package of claim 4, wherein the first insulating layer and the second insulating layer comprise different materials from each other.

6. The semiconductor package of claim 5, wherein the first insulating layer comprises an epoxy molding compound (EMC) or an Ajinomoto build-up film (ABF), and
wherein the second insulating layer comprises a photoimageable dielectric material.

7. The semiconductor package of claim 4, wherein the conductive post is coupled to a top surface of the interconnection pattern.

8. The semiconductor package of claim 4, wherein the interconnection pattern comprises:
a head portion on a top surface of the second insulating layer; and
a tail portion extending through the second insulating layer vertically and connected to a bottom surface of the head portion,
wherein a width of the tail portion is smaller than a width of the head portion.

9. The semiconductor package of claim 4, wherein the plurality of pads have a thickness that is equal to or smaller than a thickness of the interconnection pattern, and the plurality of pads have a width that is equal to or smaller than a width of the interconnection pattern.

10. The semiconductor package of claim 1, wherein the plurality of pads have a thickness ranging from 5 μm to 20 μm, and
wherein a distance between two adjacent pads of the plurality of pads ranges from 10 μm to 150 μm.

11. The semiconductor package of claim 1, wherein the plurality of top surfaces of the plurality of pads are coplanar with the top surface of the first insulating layer, and
wherein the plurality of bottom surfaces of the plurality of pads are coplanar with the bottom surface of the first insulating layer.

12. The semiconductor package of claim 1, wherein an inactive surface of the bridge chip is attached to the top surface of the first redistribution layer, and
wherein the bridge chip comprises a plurality of bumps on a top surface of the bridge chip.

13. The semiconductor package of claim 12, wherein a top surface of the conductive post, a top surface of the mold layer, and a plurality of top surfaces of the plurality of bumps are substantially flat and are coplanar with each other.

14. (canceled)

15. A semiconductor package comprising:
a first redistribution layer;
a bridge chip on the first redistribution layer;
a mold layer on the first redistribution layer, the mold layer enclosing the bridge chip;
a second redistribution layer disposed on the mold layer;
a conductive post extending through the mold layer vertically and connecting the first redistribution layer and the second redistribution layer; and
a first semiconductor chip mounted on the second redistribution layer,
wherein the first redistribution layer comprises:
a substrate protection layer;
a pad layer that includes a plurality of outer pads extending through the substrate protection layer vertically, a top surface of the substrate protection layer and a plurality of top surfaces of the plurality of outer pads being substantially flat and being coplanar with each other;
an insulating pattern covering the substrate protection layer and the plurality of outer pads; and
a plurality of interconnection patterns disposed on the insulating pattern,
wherein each interconnection pattern of the plurality of interconnection patterns comprises:
a head portion on a top surface of the insulating pattern; and
a tail portion extended from a bottom surface of the head portion through the insulating pattern vertically and connected to the plurality of outer pads,
wherein a total thickness variation (TTV) of the pad layer ranges from 0 μm to 10 μm.

16. The semiconductor package of claim 15, wherein a surface flatness of a top surface of the pad layer is greater than a surface flatness of a bottom surface of the pad layer.

17. The semiconductor package of claim 15, wherein each outer pad of the plurality of outer pads has a uniform width in a vertical direction.

18. The semiconductor package of claim 15, wherein the plurality of top surfaces of the plurality of outer pads are exposed to an outside of the substrate protection layer near the top surface of the substrate protection layer, and
wherein a plurality of bottom surfaces of the plurality of outer pads are exposed to the outside of the substrate protection layer near a bottom surface of the substrate protection layer.

19. The semiconductor package of claim 15, wherein the substrate protection layer and the insulating pattern comprise different materials from each other.

20. (canceled)

21. The semiconductor package of claim 15, wherein the plurality of outer pads have a thickness that is equal to or smaller than a thickness of the plurality of interconnection patterns, and wherein the plurality of outer pads have a width that is equal to or smaller than a width of the plurality of interconnection patterns.

22.-23. (canceled)

24. A semiconductor package comprising:
a first redistribution layer;
a second redistribution layer disposed on the first redistribution layer;
a bridge chip mounted on a bottom surface of the second redistribution layer;
a mold layer enclosing the bridge chip, the mold layer between the first redistribution layer and the second redistribution layer;
a conductive post extending through the mold layer vertically and connecting the first redistribution layer and the second redistribution layer;
a first semiconductor chip mounted on a top surface of the second redistribution layer; and
a chip stack including a plurality of second semiconductor chips that are vertically stacked on the top surface of the second redistribution layer and that are horizontally spaced apart from the first semiconductor chip,
wherein the first redistribution layer comprises:
a pad layer including a plurality of outer pads and a substrate protection layer that horizontally encloses the plurality of outer pads;
an insulating pattern covering the plurality of outer pads and the substrate protection layer; and
an interconnection pattern disposed on the insulating pattern, extending through the insulating pattern, and coupled to the plurality of outer pads,
wherein a plurality of top surfaces of the plurality of outer pads are exposed to an outside of the substrate protection layer near a top surface of the substrate protection layer,
wherein a top surface of the pad layer is substantially flat,
wherein a plurality of bottom surfaces of the plurality of outer pads are exposed to the outside of the substrate protection layer near a bottom surface of the substrate protection layer, and
wherein a bottom surface of the pad layer is uneven.

25.-35. (canceled)
